(19) United States
(12) Patent Application Publication
(10) Pub. No.: US 2026/0047210 A1
(43) Pub. Date: Feb. 12, 2026

(54) INTEGRATED CIRCUIT, SYSTEM AND METHOD OF FORMING THE SAME

(71) Applicant: TAIWAN SEMICONDUCTOR MANUFACTURING COMPANY, LTD., Hsinchu (TW)

(72) Inventors: Ching-Yu HUANG, Hsinchu (TW); Kuan Yu CHEN, Hsinchu (TW); Yuan Yu HUANG, Hsinchu (TW); Wei-Cheng LIN, Hsinchu (TW); Jiann-Tyng TZENG, Hsinchu (TW)

(21) Appl. No.: 18/968,582

(22) Filed: Dec. 4, 2024

Related U.S. Application Data
(60) Provisional application No. 63/680,876, filed on Aug. 8, 2024.

(51) Int. Cl. H10D 89/10; H03K 19/0185

(52) U.S. Cl. CPC H10D 89/10; H03K 19/01855

(57) ABSTRACT

An integrated circuit includes a first cell region including a first set of transistors of a clock circuit, and a second cell region adjacent to the first cell region along a first boundary. The second cell region includes a feed-through via extending from a front-side to a back-side of a substrate, and being configured to electrically couple elements on the front-side and the back-side together. The feed-through via includes a first conductor on the back-side of the substrate, a second conductor being on a first level and being above the first conductor, a first contact being on a second level, and being above the first conductor, and a first via being on a third level, and being above the first conductor.

### PRIORITY CLAIM

This application claims the benefit of U.S. Provisional Application No. 63/680,876, filed Aug. 8, 2024, which is herein incorporated by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of an integrated circuit, in accordance with some embodiments.

FIGS. 2A-2H are corresponding diagrams of a corresponding integrated circuit, in accordance with some embodiments.

FIGS. 3A-3C are diagrams of an integrated circuit, in accordance with some embodiments.

FIG. 4 is a diagram of an integrated circuit, in accordance with some embodiments.

FIG. 5A is a top view of integrated circuit, in accordance with some embodiments.

FIGS. 5B-5C are corresponding cross-sectional views of integrated circuit, in accordance with some embodiments.

FIG. 6A is a top view of integrated circuit, in accordance with some embodiments.

FIGS. 6B-6D are corresponding cross-sectional views of one or more integrated circuits, in accordance with some embodiments.

FIG. 7A is a top view of integrated circuit, in accordance with some embodiments.

FIG. 7B is a top view of integrated circuit, in accordance with some embodiments.

FIG. 8A is a top view of integrated circuit, in accordance with some embodiments.

FIG. 8B is a top view of a portion of integrated circuit, in accordance with some embodiments.

FIG. 9A is a top view of integrated circuit, in accordance with some embodiments.

FIG. 9B is a top view of a portion of integrated circuit, in accordance with some embodiments.

FIG. 10A is a top view of integrated circuit, in accordance with some embodiments.

FIG. 10B is a top view of a portion of integrated circuit, in accordance with some embodiments.

FIG. 11A is a top view of a portion of an integrated circuit, in accordance with some embodiments.

FIG. 11B is a top view of a portion of integrated circuit, in accordance with some embodiments.

FIG. 11C is a top view of a portion of integrated circuit, in accordance with some embodiments.

FIG. 12A is a top view of a portion of an integrated circuit, in accordance with some embodiments.

FIG. 12B is a top view of a portion of integrated circuit, in accordance with some embodiments.

FIG. 12C is a top view of a portion of integrated circuit, in accordance with some embodiments.

FIG. 13A is a top view of a portion of an integrated circuit, in accordance with some embodiments.

FIG. 13B is a top view of a portion of integrated circuit, in accordance with some embodiments.

FIG. 13C is a top view of a portion of integrated circuit, in accordance with some embodiments.

FIGS. 14A-14B are functional flow charts of method of manufacturing an IC device, in accordance with some embodiments.

FIG. 15 is a flowchart of a method of forming or manufacturing an integrated circuit in accordance with some embodiments.

FIG. 16 is a flowchart of a method of generating a layout design of an integrated circuit, in accordance with some embodiments.

FIG. 17 is a schematic view of a system for designing an IC layout design and manufacturing an IC circuit in accordance with some embodiments.

FIG. 18 is a block diagram of an integrated circuit (IC) manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit includes a first cell region extending in a first direction and having a first height in a second direction different from the first direction.

In some embodiments, the first cell region includes a first set of transistors of a clock circuit.

In some embodiments, the integrated circuit further includes a second cell region extending in the first direction and having a second height in the second direction. In some embodiments, the second height is different from the first height. In some embodiments, the second cell region is adjacent to the first cell region along a first boundary. In some embodiments, the first boundary extends in the first direction.

In some embodiments, the second cell region includes a feed-through via extending from a front-side to a back-side of a substrate. In some embodiments, the feed-through via is configured to electrically couple elements on the front-side and the back-side together.

In some embodiments, the feed-through via includes a first conductor on the back-side of the substrate, and extending in the first direction.

In some embodiments, the feed-through via further includes a second conductor extending in the first direction, being on a first level and being above the first conductor.

In some embodiments, the feed-through via (FTV) further includes a first contact extending in at least the first direction or the second direction, being on a second level different from the first level, and being above the first conductor.

In some embodiments, the feed-through via further includes a first via extending in the first direction, being on a third level different from the first level and the second level, and being above the first conductor.

In some embodiments, the integrated circuit is configured to provide a cell to FTV electrical connection between the FTV and the first cell region. In some embodiments, by electrically the FTV and the first cell region together, the FTV is configured to send/receive an output signal to/from the first cell region while being located outside of the first cell region, and thus not occupying area within the first cell region.

In some embodiments, by electrically connecting the FTV and first cell region together, the FTV is configured to send/receive an output signal to/from the first cell region while reducing the resistance and/or capacitance of the FTVs thereby reducing the resistance and/or capacitance of a clock tree by using backside routing compared to other approaches.

In some embodiments, by reducing the resistance and/or capacitance of the clock tree, the integrated circuit has less clock cell delay than other approaches, thereby improving the performance of clock cells and/or clock trees of the integrated circuit compared to other approaches.

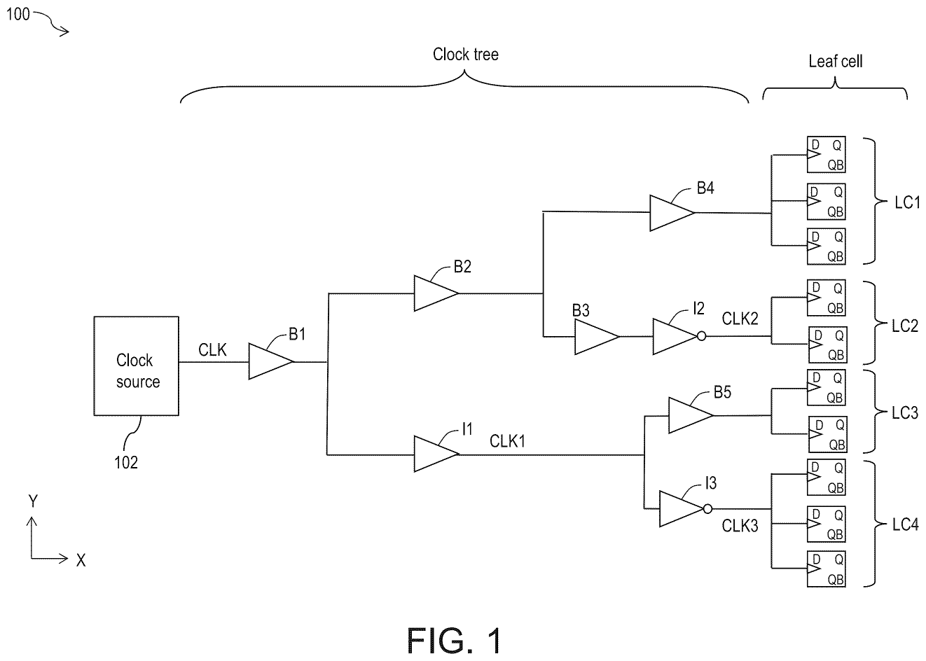

FIG. 1 is a circuit diagram of an integrated circuit 100, in accordance with some embodiments.

In some embodiments, integrated circuit 100 is a clock tree circuit. In some embodiments, the clock tree circuit is configured to deliver the clock signal CLK to each leaf cell LC1, LC2, LC3 or LC4 with balanced timing.

Integrated circuit 100 includes a clock source 102, inverters I1, I2 and I3, buffers B1, B2, B3, B4 and B5 and leaf cells LC1, LC2, LC3 and LC4.

Clock source 102 is coupled to an input terminal of buffer B1. In some embodiments, clock source 102 is configured to generate a clock signal CLK.

In some embodiments, one or more of buffer B1, B2, B3, B4 or B5 is configured to buffer were delay the clock signal CLK.

An output terminal of buffer B1 is coupled to an input terminal of buffer B2 and an input terminal of an inverter I1. Buffer B1 is configured to receive the clock signal CLK. An output terminal of buffer B1 is configured to output the clock signal CLK.

Buffer B2 is coupled to an input terminal of a buffer B3 and an input terminal of a buffer B4. Buffer B2 is configured to receive the clock signal CLK. An output terminal of buffer B2 is configured to output the clock signal CLK to an input terminal of buffer B3 and an input terminal of buffer B4.

Buffer B3 is coupled to an input terminal of an inverter I2. Buffer B3 is configured to receive the clock signal CLK. An output terminal of buffer B3 is configured to output the clock signal CLK to an input terminal of inverter I2.

Buffer B4 is coupled to input terminals of corresponding leaf cells LC1. Buffer B4 is configured to receive the clock signal CLK. An output terminal of buffer B4 is configured to output the clock signal CLK to an input terminal of leaf cells LC1.

Leaf cells LC1 are configured to receive the clock signal CLK. In some embodiments, one or more of leaf cells LC1, LC2, LC3 or LC4 includes one or more components of memory, macros or standard cells.

Inverter I2 is coupled to input terminals of corresponding leaf cells LC2. Inverter I2 is configured to receive the clock signal CLK. An output terminal of inverter I2 is configured to output an inverted clock signal CLK2 to an input terminal of leaf cells LC2. In some embodiments, the inverted clock signal CLK2 is inverted from the clock signal CLK and vice versa.

Leaf cells LC2 are configured to receive the inverted clock signal CLK2.

Inverter I1 is coupled to an input terminal of a buffer B5 and an input terminal of an inverter I3. Inverter I1 is configured to generate an inverted clock signal CLK1. In some embodiments, the inverted clock signal CLK1 is inverted from the clock signal CLK and vice versa. Inverter I1 is configured to receive the clock signal CLK. An output terminal of inverter I1 is configured to output the inverted clock signal CLK1 to an input terminal of buffer B5 and an input terminal of inverter I3.

Buffer B5 is coupled to input terminals of corresponding leaf cells LC3. Buffer B5 is configured to receive the inverted clock signal CLK1. An output terminal of buffer B5 is configured to output the inverted clock signal CLK1 to an input terminal of leaf cells LC3.

Leaf cells LC3 are configured to receive the inverted clock signal CLK1.

Inverter I3 is coupled to input terminals of corresponding leaf cells LC4. Inverter I3 is configured to receive the inverted clock signal CLK1. An output terminal of inverter I3 is configured to output a clock signal CLK3 to an input terminal of leaf cells LC4. In some embodiments, the clock signal CLK3 is inverted from the inverted clock signal CLK1 and vice versa. In some embodiments, the clock signal CLK3 is a delayed version of the clock signal CLK.

Leaf cells LC4 are configured to receive the inverted clock signal CLK3.

In some embodiments, one or more of leaf cells LC1, LC2, LC3 or LC4 is a single leaf cell.

Other numbers of inverters I1, I2 or I3, buffers B1, B2, B3, B4 or B5 or leaf cells LC1, LC2, LC3 or LC4 are within the scope the present disclosure. In some embodiments, other numbers of circuit branches for integrated circuit 100 are within the scope of the present disclosure.

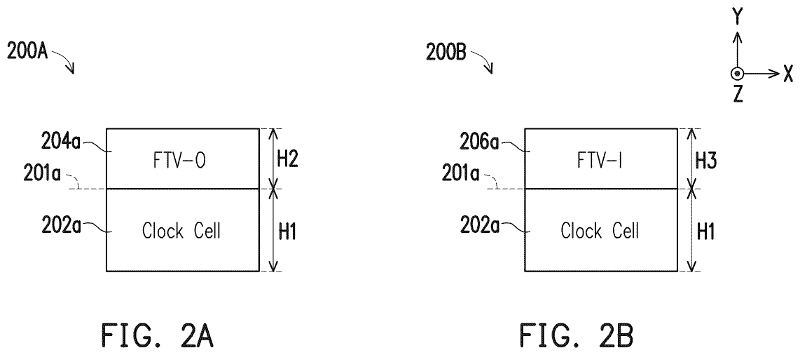

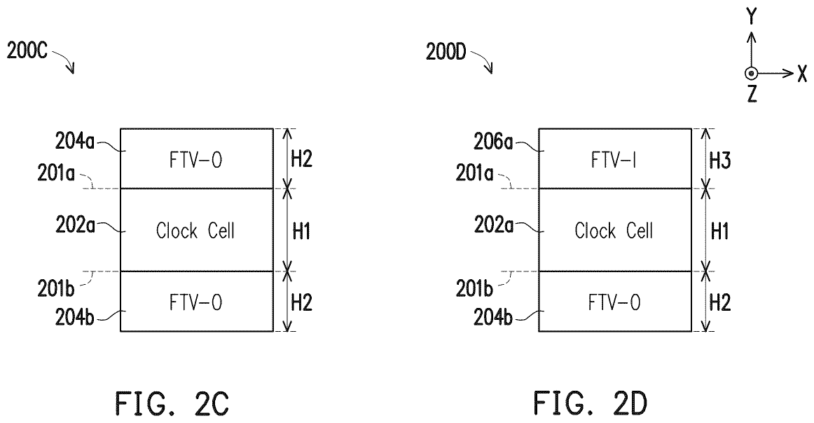

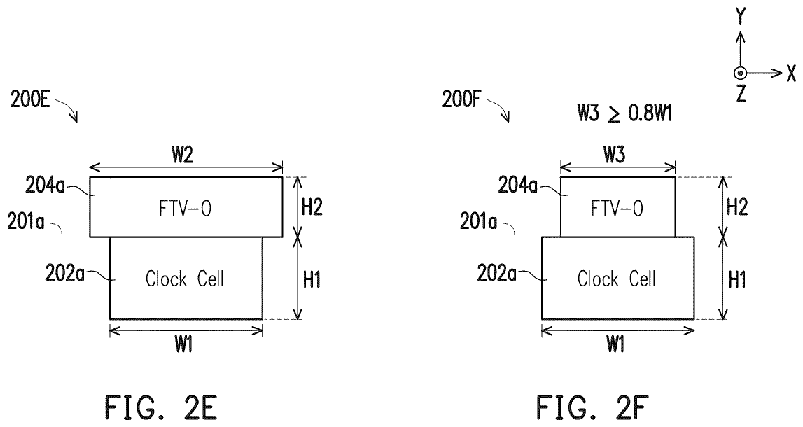

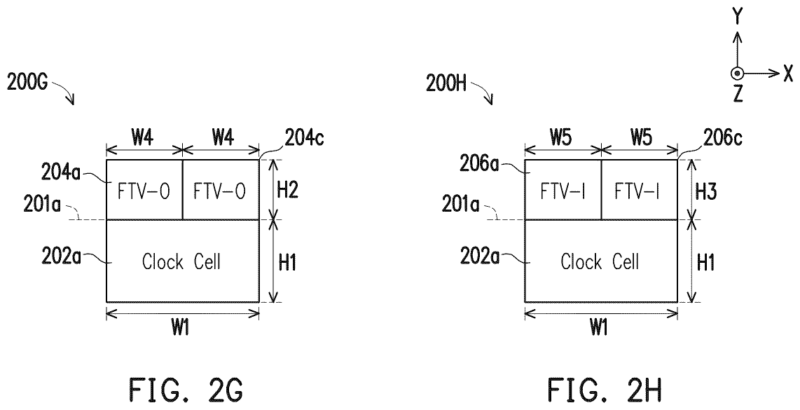

FIGS. 2A-2H are corresponding diagrams of a corresponding integrated circuit 200A-200H, in accordance with some embodiments.

In some embodiments, FIGS. 2A-2H are corresponding floorplans of corresponding integrated circuit 200A-200H, in accordance with some embodiments.

FIG. 2A is a diagram of an integrated circuit 200A, in accordance with some embodiments.

Integrated circuit 200A includes a cell 202a and a cell 204a.

In some embodiments, cell 202a is a region of a clock circuit, and the clock circuit includes one or more buffers or inverters. In some embodiments, cell 202a is integrated circuit 100. In some embodiments, In some embodiments, cell 202a includes one or more of the buffers, inverters or leaf cells of integrated circuit 100.

In some embodiments, cell 204a is a region of a feed-through via (FTV) circuit. In some embodiments, an FTV circuit extends from a front-side of a substrate to a back-side of the substrate and vice versa. In some embodiments, the FTV circuit is configured to route signals from the front-side of the substrate to the back-side of the substrate and vice versa.

In some embodiments, cell 204a is referred to as an FTV-output (FTV-O) cell. In some embodiments, an FTV-O cell is configured to receive an output signal from other clock cells, such as cell 202a.

Cell 202a and cell 204a are configured to share a common boundary 201a. Boundary 201a extends in a first direction X. In some embodiments, cell 202a and cell 204a are adjacent with or directly next to each other along boundary 201a.

Cell 202a has a height H1 in a second direction Y. in some embodiments, the second direction Y is different from the first direction X.

Cell 204a has a height H2 in a second direction Y.

In some embodiments, the height H2 is different from the height H1. In some embodiments, the height H2 is less than the height H1.

In some embodiments, a width of cell 204a in the first direction X is at least 80% as wide as a width of cell 202a in the first direction X. In some embodiments, the width of cell 202a in the first direction X is greater than the height H1. In some embodiments, the width of cell 204a in the first direction X is greater than the height H2.

In some embodiments, at least one of cell 202a, 204a, 204b, 204c, 206a, 206b or 206c is a single height cell. In some embodiments, at least one of cell 202a, 204a, 204b, 204c, 206a, 206b or 206c is a double height cell.

Other configurations, arrangements on other levels or quantities of cells 202a or 204a in integrated circuit 200A are within the scope of the present disclosure.

FIG. 2B is a diagram of an integrated circuit 200B, in accordance with some embodiments.

Integrated circuit 200B includes a cell 202a and a cell 206a.

Integrated circuit 200B is a variation of integrated circuit 200A, and similar detailed description is therefore omitted. In comparison with integrated circuit 200A, cell 206a of integrated circuit 200B replaces cell 204a, and similar detailed description is therefore omitted.

In some embodiments, cell 206a is referred to as an FTV-input (FTV-I) cell. In some embodiments, an FTV-I cell is configured to output an input signal to other clock cells, such as cell 202a.

Cell 202a and cell 206a are configured to share the common boundary 201a. In some embodiments, cell 202a and cell 206a are adjacent with or directly next to each other along boundary 201a.

Cell 206a has a height H3 in a second direction Y.

In some embodiments, the height H3 is different from the height H1. In some embodiments, the height H3 is less than the height H1.

In some embodiments, a width of cell 206a in the first direction X is at least 80% as wide as a width of cell 202a in the first direction X. In some embodiments, the width of cell 202a in the first direction X is greater than the height H1. In some embodiments, the width of cell 206a in the first direction X is greater than the height H3.

Other configurations, arrangements on other levels or quantities of cells 202a or 206a in integrated circuit 200B are within the scope of the present disclosure.

FIG. 2C is a diagram of an integrated circuit 200C, in accordance with some embodiments.

Integrated circuit 200C includes a cell 202a, a cell 204a and a cell 204b.

Integrated circuit 200C is a variation of integrated circuit 200A, and similar detailed description is therefore omitted. In comparison with integrated circuit 200A, integrated circuit 200C further includes cell 204b, and similar detailed description is therefore omitted.

In some embodiments, cell 204b is similar to cell 204a, and similar detailed description is therefore omitted.

In some embodiments, cell 204a and cell 204b are referred to as FTV-O cells, and at least one of cell 204a or 204b is configured to receive an output signal from other clock cells, such as cell 202a.

Cell 202a and cell 204b are configured to share a common boundary 201b. Boundary 201b extends in the first direction X. In some embodiments, cell 202a and cell 204b are adjacent with or directly next to each other along boundary 201b.

Cell 204b has the height H2 in the second direction Y.

In some embodiments, cell 204b has a height different from a height of cell 204a.

In some embodiments, a width of cell 204b in the first direction X is at least 80% as wide as a width of cell 202a in the first direction X. In some embodiments, the width of cell 204b in the first direction X is greater than the height H1.

Other configurations, arrangements on other levels or quantities of cells 202a, 204a or 204b in integrated circuit 200C are within the scope of the present disclosure.

FIG. 2D is a diagram of an integrated circuit 200D, in accordance with some embodiments.

Integrated circuit 200D includes cell 202a, cell 206a and cell 204b.

Integrated circuit 200D is a variation of integrated circuit 200B and 200C, and similar detailed description is therefore omitted. In comparison with integrated circuit 200B, integrated circuit 200D further includes cell 204b, and similar detailed description is therefore omitted. In comparison with integrated circuit 200C, cell 206a of integrated circuit 200D replaces cell 204a of integrated circuit 200C, and similar detailed description is therefore omitted.

In some embodiments, cell 206a and cell 204b are referred to as FTV-O cells, and at least one of cell 206a or 204b is configured to receive an output signal from other clock cells, such as cell 202a.

In some embodiments, cell 206a is referred to as an FTV-I cell.

In some embodiments, cell 204b is referred to as an FTV-O cell.

In some embodiments, cell 206a is replaced with cell 204a, and cell 204b is replaced with a cell similar to cell 206a, and similar detailed description is therefore omitted.

Other configurations, arrangements on other levels or quantities of cells 202a, 206a or 204b in integrated circuit 200D are within the scope of the present disclosure.

FIG. 2E is a diagram of an integrated circuit 200E, in accordance with some embodiments.

Integrated circuit 200E includes a cell 202a and a cell 204a.

Integrated circuit 200E is a variation of integrated circuit 200A, and similar detailed description is therefore omitted. In comparison with integrated circuit 200A, a width W2 of cell 204a of integrated circuit 200E is greater than a width W1 of cell 202a of integrated circuit 200A, and similar detailed description is therefore omitted.

In some embodiments, a width W2 of cell 204a in the first direction X is greater than a width W1 of cell 202a in the first direction X. In some embodiments, the width W1 of cell 202a in the first direction X is greater than the height H1. In some embodiments, the width W2 of cell 204a in the first direction X is greater than the height H2.

In some embodiments, cell 204a is replaced with cell 206a, and similar detailed description is therefore omitted.

Other configurations, arrangements on other levels or quantities of cells 202a or 204a in integrated circuit 200E are within the scope of the present disclosure.

FIG. 2F is a diagram of an integrated circuit 200F, in accordance with some embodiments.

Integrated circuit 200F includes a cell 202a and a cell 204a.

Integrated circuit 200F is a variation of integrated circuit 200B, and similar detailed description is therefore omitted. In comparison with integrated circuit 200B, a width W3 of cell 204a of integrated circuit 200F is less than a width W1 of cell 202a of integrated circuit 200B, and similar detailed description is therefore omitted.

In some embodiments, a width W3 of cell 204a in the first direction X is less than a width W1 of cell 202a in the first direction X.

In some embodiments, cell 204a is replaced with cell 206a, and similar detailed description is therefore omitted.

Other configurations, arrangements on other levels or quantities of cells 202a or 204a in integrated circuit 200F are within the scope of the present disclosure.

FIG. 2G is a diagram of an integrated circuit 200G, in accordance with some embodiments.

Integrated circuit 200G includes a cell 202a, a cell 204a and a cell 204c.

Integrated circuit 200G is a variation of integrated circuit 200A, and similar detailed description is therefore omitted. In comparison with integrated circuit 200A, integrated circuit 200G further includes cell 204c, and similar detailed description is therefore omitted.

In some embodiments, cell 204c is similar to cell 204a, and similar detailed description is therefore omitted.

In some embodiments, cell 204a and cell 204c are referred to as FTV-O cells, and at least one of cell 204a or 204c is configured to receive an output signal from other clock cells, such as cell 202a.

Cell 202a, cell 204a and cell 204c are configured to share the common boundary 201a. In some embodiments, cell 202a, cell 204a and cell 204c are adjacent with or directly next to each other along boundary 201a.

In some embodiments, cell 204a and cell 204c are adjacent with or directly next to each other in the second direction Y.

Cell 204c and cell 204a have the height H2 in the second direction Y.

Cell 204a and 204c have a width W4 in the second direction Y.

In some embodiments, the width W4 of cell 204a or 204c in the first direction X is less than the width W1 of cell 202a in the first direction X.

In some embodiments, the width W4 is equal to 50% of width W1.

In some embodiments, cell 204a is replaced with a cell similar to cell 204a along boundary 201b, and cell 204c is replaced with a cell similar to cell 204c along boundary 201b, and similar detailed description is therefore omitted.

Other configurations, arrangements on other levels or quantities of cells 202a, 204a or 204c in integrated circuit 200G are within the scope of the present disclosure.

FIG. 2H is a diagram of an integrated circuit 200H, in accordance with some embodiments.

Integrated circuit 200H includes a cell 202a, a cell 206a and a cell 206c.

Integrated circuit 200H is a variation of integrated circuit 200B, and similar detailed description is therefore omitted. In comparison with integrated circuit 200B, integrated circuit 200H further includes cell 206c, and similar detailed description is therefore omitted.

In some embodiments, cell 206c is similar to cell 206a, and similar detailed description is therefore omitted.

In some embodiments, cell 206a and cell 206c are referred to as FTV-I cells, and at least one of cell 206a or 206c is configured to output an input signal to other clock cells, such as cell 202a.

Cell 202a, cell 206a and cell 206c are configured to share the common boundary 201a. In some embodiments, cell 202a, cell 206a and cell 206c are adjacent with or directly next to each other along boundary 201a.

In some embodiments, cell 206a and cell 206c are adjacent with or directly next to each other in the second direction Y.

Cell 206c and cell 206a have the height H3 in the second direction Y.

Cell 206a and 206c have a width W5 in the second direction Y.

In some embodiments, the width W5 of cell 206a or 206c in the first direction X is less than the width W1 of cell 202a in the first direction X.

In some embodiments, the width W5 is equal to 50% of width W1.

In some embodiments, cell 206a is replaced with a cell similar to cell 206a along boundary 201b, and cell 206c is replaced with a cell similar to cell 206c along boundary 201b, and similar detailed description is therefore omitted.

In some embodiments, cell 206a or 206c is replaced with corresponding cell 204a or 204c along boundary 201a, and similar detailed description is therefore omitted.

Other configurations, arrangements on other levels or quantities of cells 202a, 206a or 206c in integrated circuit 200H are within the scope of the present disclosure.

In some embodiments, at least one of integrated circuit 200A-200H is configured to achieve one or more benefits described herein including the details discussed herein.

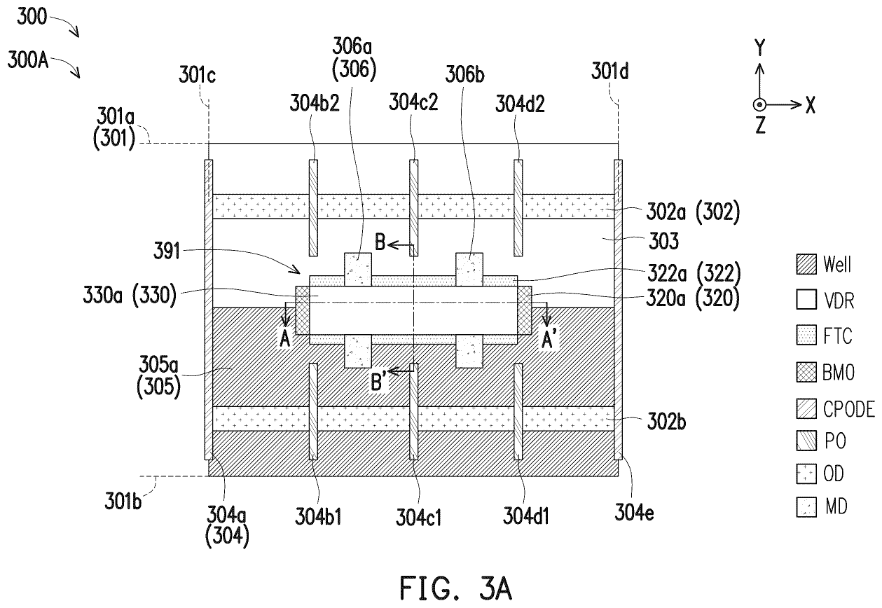

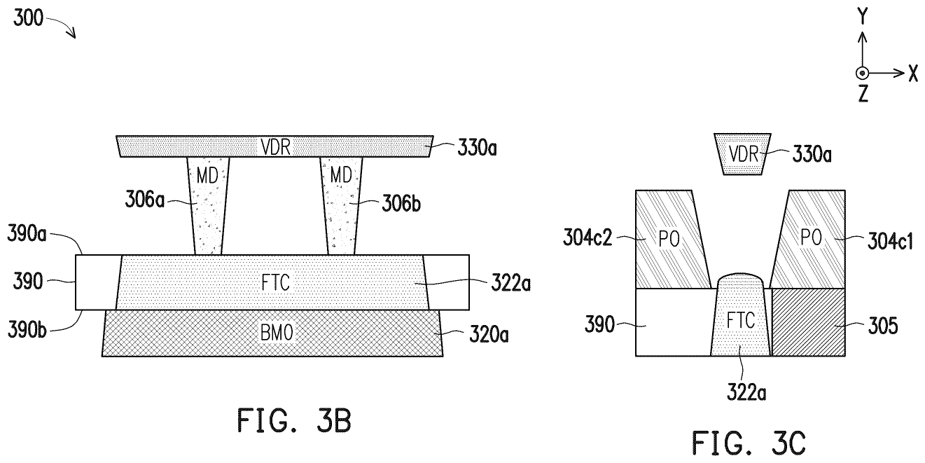

FIGS. 3A-3C are diagrams of an integrated circuit 300, in accordance with some embodiments.

Integrated circuit 300 is an embodiment of at least one of cell 204a, 204b, 204c, 206a, 206b or 206c, and similar detailed description is omitted.

FIG. 3A is a top view of integrated circuit 300, in accordance with some embodiments.

FIGS. 3B-3C are corresponding cross-sectional views of integrated circuit 300, in accordance with some embodiments.

FIG. 3B is a cross-sectional view of integrated circuit 300 as intersected by plane A-A′, in accordance with some embodiments. FIG. 3C is a cross-sectional view of integrated circuit 300 as intersected by plane B-B′, in accordance with some embodiments.

In some embodiments, integrated circuit 300 is at least one of cell 204a, 204b, 204c, 206a, 206b or 206c, and similar detailed description will not be described for brevity.

In some embodiments, integrated circuit 300 is manufactured by a corresponding layout design similar to integrated circuit 300.

For brevity FIGS. 3A-6C and 8A-13C are described as a corresponding integrated circuit 300-600 and 800-1300, but in some embodiments, FIGS. 3A-6C and 8A-13C also correspond to layout designs, structural elements of integrated circuit 300-600 and 800-1300 also correspond to layout patterns, and structural relationships including alignment, lengths and widths, as well as configurations and layers of a corresponding layout design of integrated circuit 300-600 and 800-1300 are similar to the structural relationships and configurations and layers of integrated circuit 300-600 and 800-1300, and similar detailed description will not be described for brevity.

For ease of illustration, some of the labeled elements of one or more of FIGS. 3A-6C and 8A-13C are not labelled in one or more of FIGS. 3A-6C and 8A-13C. In some embodiments, at least one or more of integrated circuit 300-600 and 800-1300 includes additional elements not shown in FIGS. 3A-6C and 8A-13C.

Integrated circuit 300 includes one or more features of an oxide diffusion (OD) level or an active level, a gate (POLY) level, a metal over diffusion (MD) level, a back-side metal 0 (BM0) level, a feed-through contact (FTC) level, and a via to MD power rail (VDR) level.

Integrated circuit 300 includes a cell 301. The cell 301 has cell boundaries 301a and 301b that extend in the first direction X, and cell boundaries 301c and 301d that extend in the second direction Y. In some embodiments, the second direction Y is different from the first direction X. In some embodiments, integrated circuit 300 abuts other cell layout designs (not shown) along cell boundaries 301c and 301d. In some embodiments, integrated circuit 300 abuts other cell layout designs (not shown) along cell boundaries 301a and 301b that extend in the first direction X. In some embodiments, integrated circuit 300 is a single height standard cell. In some embodiments, integrated circuit 300 is a double height standard cell. Other standard cell heights for integrated circuit 300 are within the scope of the present disclosure.

In some embodiments, cell 301 is a standard cell, and integrated circuit 300 corresponds to a layout of a standard cell defined by cell boundaries 301a, 301b, 301c and 301d. In some embodiments, a cell 301 is a predefined portion of integrated circuit 300 including one or more transistors and electrical connections configured to perform one or more circuit functions. In some embodiments, cell 301 is bounded by cell boundaries 301a, 301b, 301c and 301d, and thus corresponds to a region of functional circuit components or devices that are part of a standard cell.

In some embodiments, e.g., the embodiments depicted in FIGS. 3A-6C and 8A-13C discussed below, a given cell has cell boundaries 301c and 301d that are overlapped by corresponding gates 304a and 304e. In some embodiments, cell boundaries 301c and 301d of cell 301 are identified by gates 304a and 304f.

A cell is thereby configured as one or more of a standard cell, a custom cell, an engineering change order (ECO) cell, a logic gate cell, a memory cell, a custom cell, a physical device cell, or another type of cell or combination of cells capable of being defined in an IC layout diagram, similar to integrated circuit 300-600 and 800-1300. In some embodiments, at least one of cell 301, 802, 803, 902, 903, 1002, 1003, 1102, 1104, 1106, 1202, 1204, 1206, 1302 or 1304 is a standard cell of a logic gate cell. In some embodiments, a logic gate cell includes an AND, OR, NAND, NOR, XOR, INV, AND-OR-Invert (AOI), OR-AND-Invert (OAI), MUX, Flip-flop, BUFF, Latch, delay, or clock cells. In some embodiments, one or more of integrated circuit 300-600 and 800-1300 is a layout design of a memory cell. In some embodiments, a memory cell includes a static random access memory (SRAM), a dynamic RAM (DRAM), a resistive RAM (RRAM), a magnetoresistive RAM (MRAM) or read only memory (ROM). In some embodiments, one or more of integrated circuit 300-600 and 800-1300 includes one or more active or passive elements. Examples of active elements include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), or the like), FinFETs, nanosheet transistors, nanowire transistors, complementary FETs (CFETs) and planar MOS transistors with raised source/drain. Examples of passive elements include, but are not limited to, capacitors, inductors, fuses, and resistors. In some embodiments, at least integrated circuit 300-600 and 800-1300 is a standard cell. In some embodiments, one or more of integrated circuit 300-600 and 800-1300 is a logic gate cell.

In some embodiments, one or more of integrated circuit 300-600 and 800-1300 is a clock tree, such as integrated circuit 100. In some embodiments, one or more of integrated circuit 300-600 is a feed-through via (FTV).

Integrated circuit 300 further includes a substrate 390. The substrate 390 has a front-side 390a and a back-side 390b opposite from the front-side. The substrate 390 includes a well 305.

In some embodiments, the well 305 includes a first dopant type impurity. In some embodiments, the first dopant type is a p-type dopant impurity, and the well 305 is referred to as a P-type well.

In some embodiments, the first dopant type is an n-type dopant impurity, and the well 305 is referred to as an N-type well.

Integrated circuit 300 further includes one or more active regions 302a or 302b (collectively referred to as a “set of active regions 302”) extending in the first direction X.

The set of active regions 302 is embedded in the substrate 390 or the well 305.

Active region 302a is embedded in the substrate 390, and active region 302b is embedded in the well 305.

In some embodiments, active region 302b is an n-type dopant impurity, the first well is a P-well, and active region 302b corresponds to N-type transistors, and active region 302a corresponds to P-type transistors.

In some embodiments, active region 302b is a p-type dopant impurity, the first well is an N-well, and active region 302b corresponds to P-type transistors, and active region 302a corresponds to N-type transistors.

Active regions 302a, 302b of the set of active regions 302 are separated from one another in the second direction Y. In some embodiments, the set of active regions 302 are located on the front-side 390a of at least integrated circuit 300-600 and 800-1300.

In some embodiments, the set of active regions 302 is manufactured by a set of active region layout patterns similar to the set of active regions 302, and similar detailed description will not be described for brevity. In some embodiments, active regions 302a, 302b of the set of active regions 302 are manufactured by corresponding active region layout patterns similar to active regions 302a, 302b of the set of active regions 302 of integrated circuit 300-600 and 800-1300.

In some embodiments, the set of active regions 302 is referred to as an oxide diffusion (OD) region which defines the source or drain diffusion regions of at least integrated circuit 300-600 and 800-1300.

In some embodiments, active region 302a is source and drain regions of PMOS transistors of integrated circuits 300-600 and 800-1300, and active region 302b is source and drain regions of NMOS transistors of integrated circuits 300-600 and 800-1300.

In some embodiments, active region 302a is source and drain regions of NMOS transistors of integrated circuits 300-600 and 800-1300, and active region 302b is source and drain regions of PMOS transistors of integrated circuits 300-600 and 800-1300.

In some embodiments, the set of active regions 302 is located on a first level. In some embodiments, the first level corresponds to an active level or an OD level of one or more of integrated circuits 300-600 and 800-1300.

In some embodiments, active region 302a is source and drain regions of one or more n-type CFET, n-type finFET transistors, n-type nanosheet transistors or n-type nanowire transistors, and active region layout pattern 302b is source and drain regions of one or more p-type CFET, p-type finFET transistors, p-type nanosheet transistors or p-type nanowire transistors.

In some embodiments, active region 302a is source and drain regions of one or more p-type CFET, p-type finFET transistors, p-type nanosheet transistors or p-type nanowire transistors, and active region layout pattern 302b is source and drain regions of one or more n-type CFET, n-type finFET transistors, n-type nanosheet transistors or n-type nanowire transistors.

Other numbers of active regions in the set of active regions 302 are within the scope of the present disclosure.

Other configurations, arrangements on other levels or quantities of patterns in the set of active regions 302 are within the scope of the present disclosure.

Integrated circuit 300 further includes an insulating region 303.

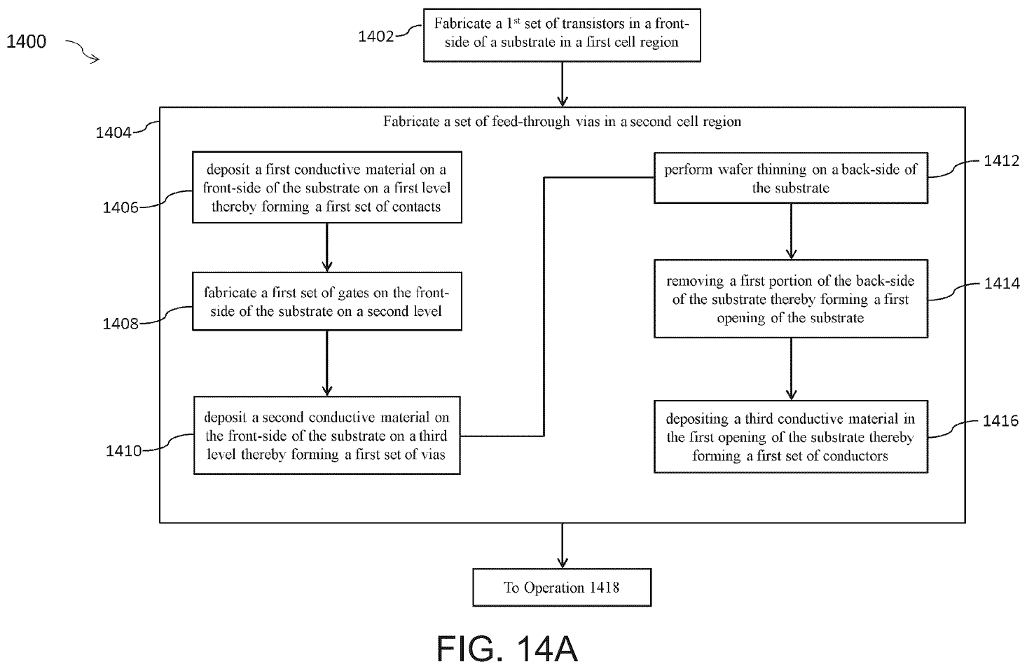

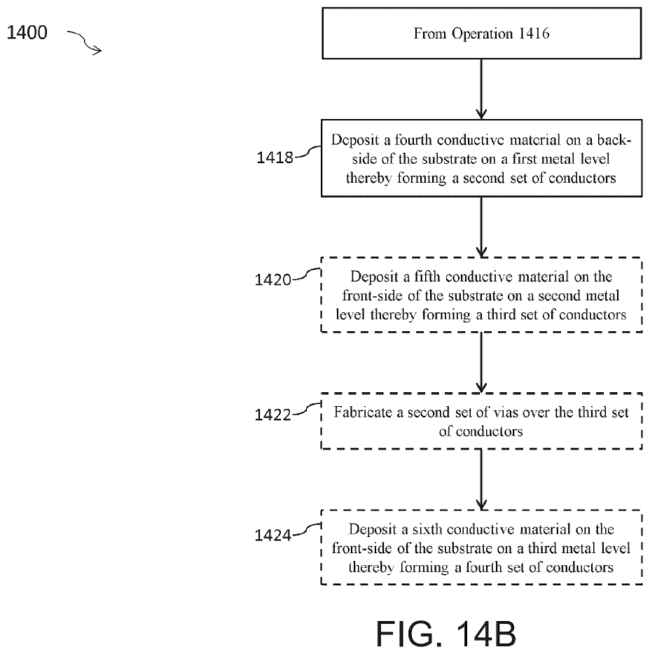

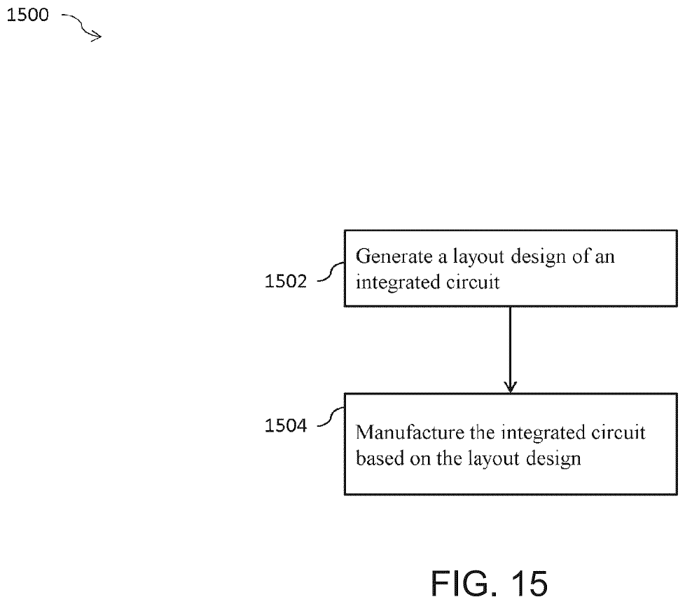

Insulating region 303 is configured to electrically isolate one or more elements of the set of active regions 302, the set of gates 304, the set of contacts 306 from one another. In some embodiments, insulating region 303 includes multiple insulating regions deposited at different times from each other during method 1400-1500 (FIGS. 14A-15). In some embodiments, insulating region is a dielectric material. In some embodiments, the dielectric material includes silicon dioxide, silicon oxy-nitride, or the like.

Other configurations, arrangements on other layout levels or other numbers of portions in insulating region 303 are within the scope of the present disclosure.

Integrated circuit 300 further includes one or more gates 304a, 304bl, 304b2, 304c1, 304c2, 304d1, 304d2 or 304e (collectively referred to as a “set of gates 304”) extending in the second direction Y. Each of the gates of the set of gates 304 is separated from an adjacent gate of the set of gates 304 in the first direction X by a first pitch (not labelled).

The set of gates 304 overlaps the set of active regions 302.

The set of gates 304 is manufactured by a corresponding set of gate patterns similar to the set of gates 304, and similar detailed description will not be described for brevity. In some embodiments, each gate 304a, 304bl, 304b2, 304c1, 304c2, 304d1, 304d2 or 304e of the set of gates 304 is manufactured by a corresponding gate pattern similar to corresponding gate 304a, 304bl, 304b2, 304c1, 304c2, 304d1, 304d2 or 304e, and similar detailed description will not be described for brevity.

In some embodiments, at least gate 304b1, 304c1 or 304d1 is a corresponding gate of a corresponding NMOS transistor, and at least gate 304b2, 304c2 or 304d2 is a corresponding gate of a corresponding PMOS transistor.

In some embodiments, at least gate 304b1, 304c1 or 304d1 is a corresponding gate of a corresponding PMOS transistor, and at least gate 304b2, 304c2 or 304d2 is a corresponding gate of a corresponding NMOS transistor.

In some embodiments, at least one of gates 304a or 304e is a corresponding dummy gate. In some embodiments, dummy gates are also referred to as continuous poly over diffusion edge (CPODE). In some embodiments, at least gate 304a or 304e corresponds to a dummy gate. In some embodiments, a dummy gate is a gate of a non-functional transistor.

In some embodiments, at least one of gate 304a, 304bl, 304b2, 304c1, 304c2, 304d1, 304d2 or 304e corresponds to a dummy gate.

The set of gates 304 is above the set of active regions 302. The set of gates 304 is positioned on a second level different from the first level. In some embodiments, the second level is different from the first level. In some embodiments, the second level corresponds to the POLY level of one or more of integrated circuits 300-600 and 800-1300.

In some embodiments, the POLY level is above the OD level.

Other configurations, arrangements on other levels or quantities of patterns in the set of gates 304 are within the scope of the present disclosure.

Integrated circuit 300 further includes one or more contacts 306a or 306b (collectively referred to as a “set of contacts 306”) extending in the second direction Y.

Each of the contacts of the set of contacts 306 is separated from an adjacent contact pattern of the set of contacts 306 in the first direction X. In some embodiments, the set of contacts 306 is referred to as “a set of slot contacts” or “a set of slot MD.”

The set of contacts 306 is manufactured by a corresponding set of contact patterns similar to the set of contacts 306, and similar detailed description will not be described for brevity. In some embodiments, each contact 306a or 306b of the set of contacts 306 is manufactured by a corresponding contact pattern similar to corresponding contact 306a or 306b of the set of contacts 306, and similar detailed description will not be described for brevity.

In some embodiments, the set of contacts 306 is also referred to as a set of metal over diffusion (MD) conductors.

In some embodiments, at least one of contact 306a or 306b of the set of contacts 306 is a corresponding source or drain terminal of one of the NMOS or PMOS transistors of integrated circuit 300-600 and 800-1300.

In some embodiments, the set of contacts 306 overlap the set of active regions 302. The set of contacts is located on a third level. In some embodiments, the third level corresponds to the contact level or an MD level of one or more of integrated circuit 300-600 and 800-1300. In some embodiments, the third level is the same as the second level. In some embodiments, the third level is different from the first level.

Other configurations, arrangements on other levels or quantities of patterns in the set of contacts 306 are within the scope of the present disclosure.

Integrated circuit 300 further includes one or more of conductor 320a (collectively referred to as a “set of conductors 320”) extending in at least the first direction X.

In some embodiments, each conductor 320a of the set of conductors 320 is separated from each other in at least the second direction Y.

In some embodiments, the set of conductors 320 is located on the back-side 390b of integrated circuit 300.

While conductor 320a is shown as a continuous structure, in some embodiments, conductor 320a is separated to form one or more discontinuous structures.

The set of conductors 320 is manufactured by a corresponding set of conductive feature patterns similar to the set of conductors 320, and similar detailed description will not be described for brevity. In some embodiments, conductor 320a is manufactured by a corresponding conductive feature pattern similar to conductor 320a of the set of conductors 320, and similar detailed description will not be described for brevity.

In some embodiments, the set of conductors 320 is configured to send or receive one or more signals. In some embodiments, the set of conductors 320 is configured to send or receive one or more clock signals, such as at least one of clock signal CLK or CLK3 of FIG. 1, or at least one of inverted clock signal CLK2 of FIG. 1. In some embodiments, the set of conductors 320 is configured to send or receive one or more supply voltages or reference supply voltages.

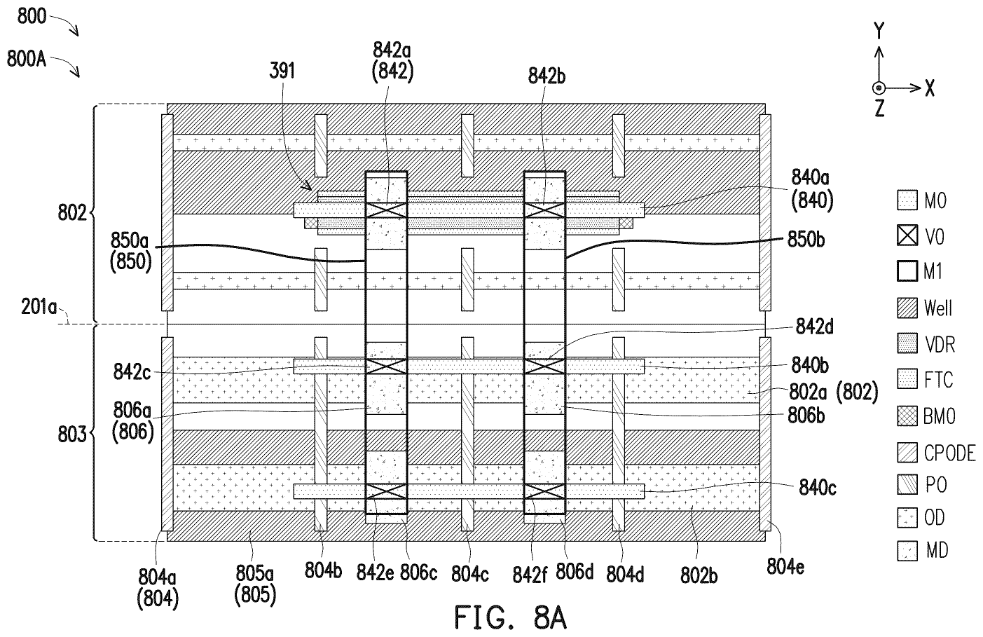

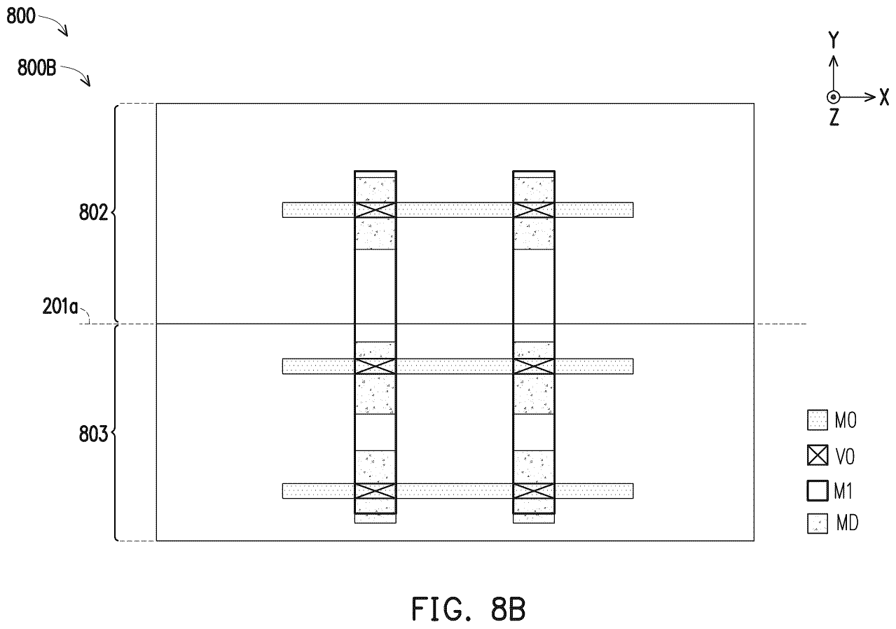

In some embodiments, the set of conductors 320 is overlapped by one or more of the set of active regions 302, the set of gates 304, the set of contacts 306, a set of conductors 322 (discussed in FIGS. 8A-8B) or a set of conductors 330 (discussed in FIGS. 8A-8B).

In some embodiments, the set of conductors 320 is on a fourth level. In some embodiments, the fourth level is different from the first level, the second level and the third level. In some embodiments, the fourth level corresponds to a BM0 level of one or more of integrated circuit 300-600 and 800-1300. In some embodiments, the BM0 level is below one or more of the OD level, the POLY level, the MD level, the FTC level, the VDR level, a metal 0 (M0) level, a via 0 (V0) level or a metal 1 (M1) level.

In some embodiments, the set of conductors 320 are located on other metal layers (e.g., back-side metal 1 (BM1), back-side metal 2 (BM2), etc.).

Each conductor in the set of conductors 320 is separated from an adjacent conductor in the set of conductors 320 in the second direction Y by a pitch (not labelled).

In some embodiments, the set of conductors 320 corresponds to BM0 routing tracks. In some embodiments, the set of conductors 320 corresponds to 1 BM0 routing track. Other numbers of BM0 routing tracks are within the scope of the present disclosure.

Other configurations, arrangements on other levels or quantities of patterns in the set of conductors 320 are within the scope of the present disclosure.

Integrated circuit 300 further includes one or more of conductor 322a (collectively referred to as a “set of conductors 322”) extending in at least the first direction X.

In some embodiments, each conductor 322a of the set of conductors 322 is separated from each other in at least the second direction Y.

In some embodiments, the set of conductors 322 is also referred to as a set of feed-through contacts or a set of contacts.

In some embodiments, the set of conductors 322 overlaps the set of conductors 320. In some embodiments, the set of conductors 322 is electrically coupled to the set of conductors 320.

In some embodiments, the set of conductors 322 is embedded in substrate 390. In some embodiments, the set of conductors 322 is embedded in an opening (not labelled) of substrate 390.

While conductor 322a is shown as a continuous structure, in some embodiments, conductor 322a is separated to form one or more discontinuous structures.

The set of conductors 322 is manufactured by a corresponding set of conductive feature patterns similar to the set of conductors 322, and similar detailed description will not be described for brevity. In some embodiments, conductor 322a is manufactured by a corresponding conductive feature pattern similar to conductor 322a of the set of conductors 322, and similar detailed description will not be described for brevity.

In some embodiments, the set of conductors 322 is configured to send or receive one or more signals. In some embodiments, the set of conductors 322 is configured to send or receive one or more clock signals, such as at least one of clock signal CLK or CLK3 of FIG. 1, or at least one of inverted clock signal CLK2 of FIG. 1. In some embodiments, the set of conductors 322 is configured to send or receive one or more supply voltages or reference supply voltages.

In some embodiments, the set of conductors 322 is overlapped by one or more of the set of gates 304, the set of contacts 306, the set of conductors 322 (discussed in FIGS. 8A-8B) or the set of conductors 330 (discussed in FIGS. 8A-8B).

In some embodiments, the set of conductors 322 is on a fifth level. In some embodiments, the fifth level is different from the first level, the second level, the third level and the fourth level. In some embodiments, the fifth level corresponds to an FTC level of one or more of integrated circuit 300-600 and 800-1300. In some embodiments, the FTC level is below one or more of the POLY level, the MD level, the VDR level, the M0 level, the V0 level or the M1 level. In some embodiments, the FTC level is above the BM0 level.

In some embodiments, the set of conductors 322 is located on other layers.

Each conductor in the set of conductors 322 is separated from an adjacent conductor in the set of conductors 322 in the second direction Y by a pitch (not labelled).

Other configurations, arrangements on other levels or quantities of patterns in the set of conductors 322 are within the scope of the present disclosure.

Integrated circuit 300 further includes one or more of conductor 330a (collectively referred to as a “set of conductors 330”) extending in at least the first direction X.

In some embodiments, each conductor 330a of the set of conductors 330 is separated from each other in at least the second direction Y.

In some embodiments, the set of conductors 330 is also referred to as a set of vias or a set of via to MD rails.

In some embodiments, the set of conductors 330 overlaps the set of contacts 306, the set of conductors 320 and the set of conductors 322. In some embodiments, the set of conductors 330 is electrically coupled to the set of contacts 306, the set of conductors 320 and the set of conductors 322.

In some embodiments, the set of contacts 306 is between the set of conductors 330 and the set of conductors 322. In some embodiments, a width of the set of conductors 330 in the first direction X is greater than a width of the set of contacts 306 in the first direction X.

In some embodiments, the set of gates 304 is between the set of conductors 330 and the set of conductors 322.

In some embodiments, the set of conductors 330 is electrically coupled to the set of contacts 306, the set of contacts 306 is electrically coupled to the set of conductors 322, and the set of conductors 322 is electrically coupled to the set of conductors 320.

While conductor 330a is shown as a continuous structure, in some embodiments, conductor 330a is separated to form one or more discontinuous structures.

The set of conductors 330 is manufactured by a corresponding set of conductive feature patterns similar to the set of conductors 330, and similar detailed description will not be described for brevity. In some embodiments, conductor 330a is manufactured by a corresponding conductive feature pattern similar to conductor 330a of the set of conductors 330, and similar detailed description will not be described for brevity.

In some embodiments, the set of conductors 330 is configured to send or receive one or more signals. In some embodiments, the set of conductors 330 is configured to send or receive one or more clock signals, such as at least one of clock signal CLK or CLK3 of FIG. 1, or at least one of inverted clock signal CLK2 of FIG. 1. In some embodiments, the set of conductors 330 is configured to send or receive one or more supply voltages or reference supply voltages.

In some embodiments, the set of conductors 330 overlaps one or more of the set of gates 304, the set of contacts 306, the set of conductors 320 or the set of conductors 322.

In some embodiments, the set of conductors 330 is on a sixth level. In some embodiments, the sixth level is different from the first level, the second level, the third level, the fourth level and the fifth level. In some embodiments, the sixth level corresponds to a VDR level of one or more of integrated circuit 300-600 and 800-1300. In some embodiments, the VDR level is above one or more of the BM0 level, the FTC level, the POLY level or the MD level. In some embodiments, the VDR level is below one or more of the M0 level, the V0 level or the M1 level.

In some embodiments, the set of conductors 330 is located on other layers.

Each conductor in the set of conductors 330 is separated from an adjacent conductor in the set of conductors 330 in the second direction Y by a pitch (not labelled).

Other configurations, arrangements on other levels or quantities of patterns in the set of conductors 330 are within the scope of the present disclosure.

In some embodiments, at least one gate of the set of gates 304 or 804 is formed using a doped or non-doped polycrystalline silicon (or polysilicon). In some embodiments, at least one gate of the set of gates 304 or 804 includes a metal, such as Al, Cu, W, Ti, Ta, TiN, TaN, NiSi, CoSi, other suitable conductive materials, or combinations thereof.

In some embodiments, at least one contact of the set of contacts 306, 406, 506, 806, or at least one conductor of the set of conductors 320, 322, 330, 840, 850, 1116, 1118, 1150, 1152, 1250 or 1350, or at least one via of the set of vias 842 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, the set of contacts 306, the set of conductors 320 and the set of conductors 322 are referred to as a feed-through via (FTV) 391.

In some embodiments, the FTV 391 extends from the front-side 390a of the substrate 390 to the back-side 390b of the substrate 390 and vice versa. In some embodiments, FTV 391 is configured to route signals from the front-side 390a of the substrate 390 to the back-side 390b of the substrate 390 and vice versa.

In some embodiments, FTV 391 is referred to as an FTV-O cell, and FTV 391 is configured to receive an output signal from other clock cells, such as cell 202a in FIG. 2A.

In some embodiments, FTV 391 is referred to as an FTV-I cell, and FTV 391 is configured to output an input signal to other clock cells, such as cell 202a in FIG. 2B.

In some embodiments, the FTV 391 is configured to send one or more signals to an adjacent cell. In some embodiments, the FTV 391 is configured to receive one or more signals from an adjacent cell, such as cell 202a in FIG. 2A. In some embodiments, the FTV 391 is configured to send or receive one or more clock signals, such as at least one of clock signal CLK or CLK3 of FIG. 1, or at least one of inverted clock signal CLK2 of FIG. 1, to a cell, such as cell 202a in FIG. 2B. In some embodiments, the FTV 391 is configured to send or receive one or more supply voltages or reference supply voltages.

In some embodiments, integrated circuit 300 is configured to achieve one or more benefits described herein including the details discussed herein.

Other configurations, arrangements on other levels or quantities of elements in integrated circuit 300 are within the scope of the present disclosure.

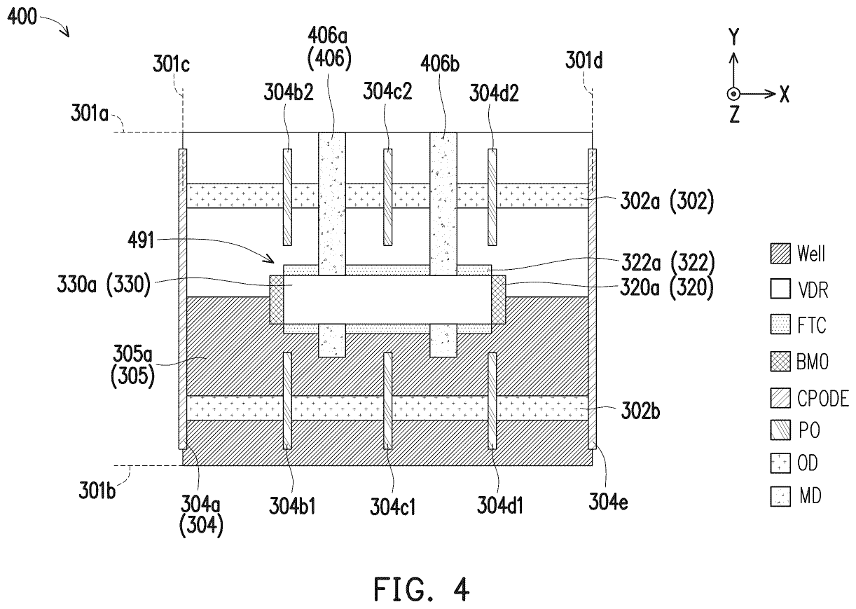

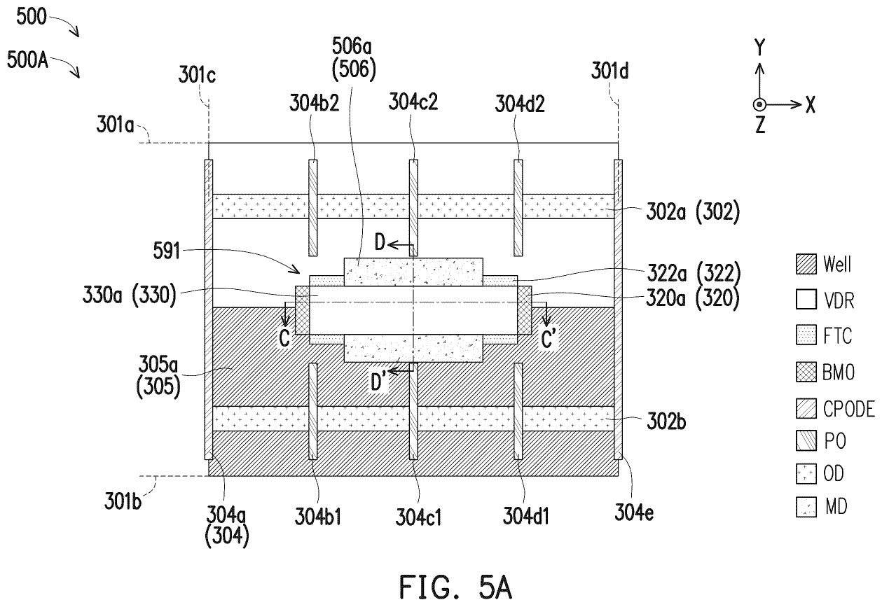

FIG. 4 is a diagram of an integrated circuit 400, in accordance with some embodiments.

Integrated circuit 400 is an embodiment of at least one of cell 204a, 204b, 204c, 206a, 206b or 206c, and similar detailed description is omitted.

FIG. 4 is a top view of integrated circuit 400, in accordance with some embodiments.

Integrated circuit 400 is manufactured by a corresponding layout design similar to integrated circuit 400.

Integrated circuit 400 is a variation of integrated circuit 300 (FIGS. 3A-3C). In comparison with integrated circuit 300 of FIGS. 3A-3C, a set of contacts 406 of integrated circuit 400 replaces the set of contacts 306, and similar detailed description is therefore omitted. In comparison with integrated circuit 300 of FIGS. 3A-3C, an FTV 491 of integrated circuit 400 replaces the FTV 391, and similar detailed description is therefore omitted.

Integrated circuit 400 includes at least the cell 301, the substrate 390, the set of active regions 302, the well 305, the insulating region 303, the set of gates 304, the set of contacts 406, the set of conductors 320, the set of conductors 322, and the set of conductors 330.

The set of contacts 406 includes at least contact 406a or 406b. In comparison with integrated circuit 300 of FIGS. 3A-3C, contact 406a or 406b of the set of contacts 406 replaces the corresponding contact 306a or 306b of the set of contacts 306, and similar detailed description is therefore omitted.

The set of contacts 406 overlap the active region 302a. The contacts 406a and 406b of the set of contacts 406 overlap the active region 302a.

The set of contacts 406 extend in the second direction to at least the cell boundary 301a. In some embodiments, the contacts 406a and 406b of the set of contacts 406 extend in the second direction to at least the cell boundary 301a.

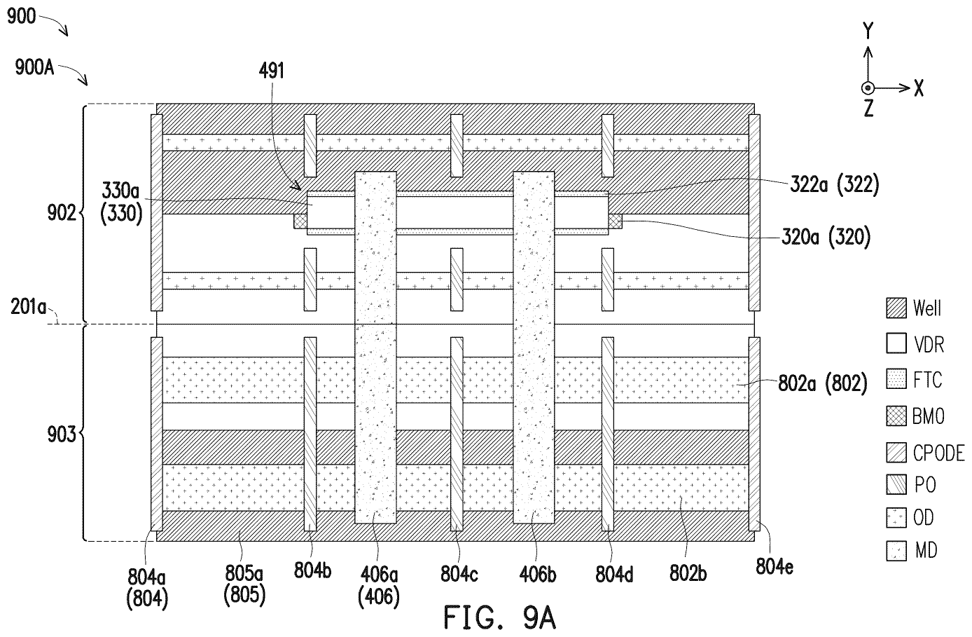

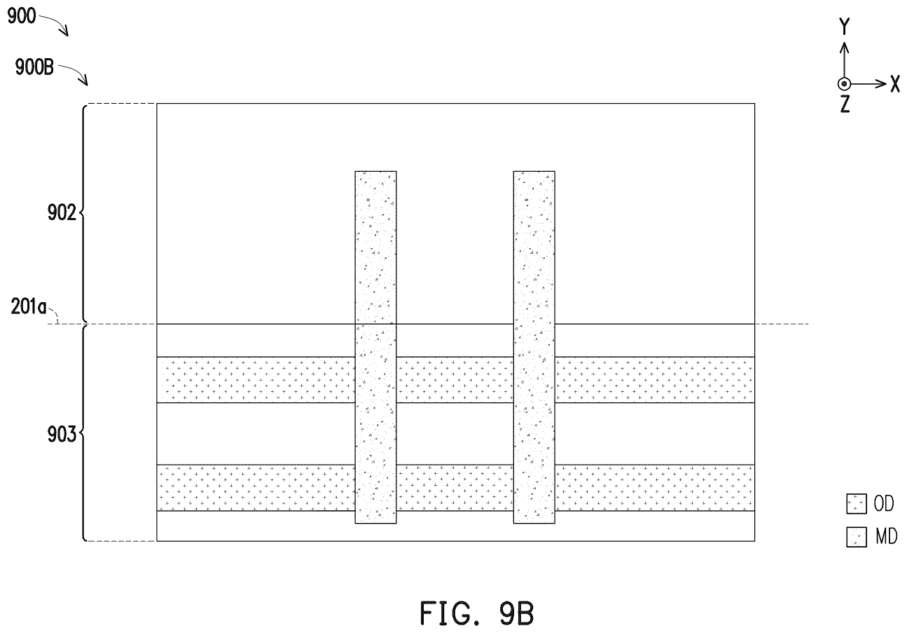

In some embodiments, the set of contacts 406 overlap the cell boundary 301a to an adjacent cell. In some embodiments, by overlapping the cell boundary 301a to an adjacent cell, the set of contacts 406 is configured to receive an output signal from the adjacent cell (e.g., as shown in FIGS. 9A-9B & 12A-12C).

In some embodiments, the contacts 406a and 406b of the set of contacts 406 overlap the cell boundary 301a to an adjacent cell. In some embodiments, by overlapping the cell boundary 301a to an adjacent cell, the contacts 406a and 406b of the set of contacts 406 are configured to receive one or more output signals from the adjacent cell (e.g., as shown in FIGS. 9A-9B & 12A-12C).

In some embodiments, the set of contacts 406 overlap the cell boundary 301b to another adjacent cell. In some embodiments, the set of contacts 406 overlap the cell boundaries 301a and 301b to corresponding adjacent cells.

Other configurations, arrangements on other levels or quantities of patterns in the set of contacts 406 are within the scope of the present disclosure.

FTV 491 includes the set of contacts 406, the set of conductors 320 and the set of conductors 322.

In some embodiments, the FTV 491 extends from the front-side 390a of the substrate 390 to the back-side 390b of the substrate 390 and vice versa. In some embodiments, FTV 491 is configured to route signals from the front-side 390a of the substrate 390 to the back-side 390b of the substrate 390 and vice versa.

In some embodiments, FTV 491 is referred to as an FTV-O cell, and FTV 491 is configured to receive an output signal from other clock cells, such as cell 202a in FIG. 2A.

In some embodiments, the FTV 491 is configured to receive one or more signals from an adjacent cell, such as cell 202a in FIG. 2A. In some embodiments, the FTV 491 is configured to receive one or more clock signals, such as at least one of clock signal CLK or CLK3 of FIG. 1, or at least one of inverted clock signal CLK2 of FIG. 1, such as cell 202a in FIG. 2A. In some embodiments, the FTV 491 is configured to receive one or more supply voltages or reference supply voltages.

In some embodiments, integrated circuit 400 is configured to achieve one or more benefits described herein including the details discussed herein.

Other configurations, arrangements on other levels or quantities of elements in integrated circuit 400 are within the scope of the present disclosure.

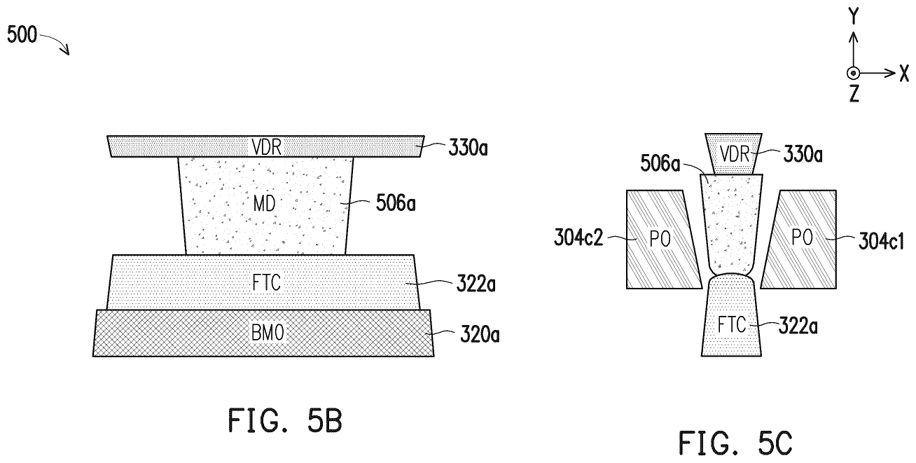

FIG. 5A is a top view of integrated circuit 500, in accordance with some embodiments.

FIGS. 5B-5C are corresponding cross-sectional views of integrated circuit 500, in accordance with some embodiments.

FIG. 5B is a cross-sectional view of integrated circuit 500 as intersected by plane C-C′, in accordance with some embodiments. FIG. 5C is a cross-sectional view of integrated circuit 500 as intersected by plane D-D′, in accordance with some embodiments.

Integrated circuit 500 is an embodiment of at least one of cell 204a, 204b, 204c, 206a, 206b or 206c, and similar detailed description is omitted.

FIG. 5 is a top view of integrated circuit 500, in accordance with some embodiments.

Integrated circuit 500 is manufactured by a corresponding layout design similar to integrated circuit 500.

Integrated circuit 500 is a variation of integrated circuit 300 (FIGS. 3A-3C). In comparison with integrated circuit 300 of FIGS. 3A-3C, a set of contacts 506 of integrated circuit 500 replaces the set of contacts 306, and similar detailed description is therefore omitted. In comparison with integrated circuit 300 of FIGS. 3A-3C, an FTV 591 of integrated circuit 500 replaces the FTV 391, and similar detailed description is therefore omitted.

Integrated circuit 500 includes at least the cell 301, the substrate 390, the set of active regions 302, the well 305, the insulating region 303, the set of gates 304, the set of contacts 506, the set of conductors 320, the set of conductors 322, and the set of conductors 330.

In comparison with integrated circuit 300 of FIGS. 3A-3C, contacts 306a and 306b of the set of contacts 306 are merged into a single contact (e.g., contact 506a of the set of contacts 506), and similar detailed description is therefore omitted.

The set of contacts 506 includes at least contact 506a. In comparison with integrated circuit 300 of FIGS. 3A-3C, contact 506a of the set of contacts 506 replaces the contacts 306a and 306b of the set of contacts 306, and similar detailed description is therefore omitted.

The set of contacts 506 overlaps the set of conductors 322 and 320. The contact 506a of the set of contacts 506 overlaps the set of conductors 322 and 320.

The set of contacts 506 extends in at least the first direction X or the second direction Y.

In some embodiments, a width of contact 506a in the first direction X is less than at least one of a width of conductor 320a in the first direction X or a width of conductor 330a in the first direction X.

In some embodiments, the width of contact 506a in the first direction X is substantially equal to about 60% to about 80% of at least one of the width of conductor 322a in the first direction X or the width of conductor 330a in the first direction X.

In some embodiments, two or more elements are substantially equal if they are different by less than 5%.

In some embodiments, the width of contact 506a in the first direction X is greater than or equal to at least one of the width of conductor 320a in the first direction X or the width of conductor 330a in the first direction X.

In some embodiments, the contact 506a is between gates 304c1 and 304c2.

Other configurations, arrangements on other levels or quantities of patterns in the set of contacts 506 are within the scope of the present disclosure.

FTV 591 includes the set of contacts 506, the set of conductors 320 and the set of conductors 322.

In some embodiments, the FTV 591 extends from the front-side 390a of the substrate 390 to the back-side 390b of the substrate 390 and vice versa. In some embodiments, FTV 591 is configured to route signals from the front-side 390a of the substrate 390 to the back-side 390b of the substrate 390 and vice versa.

In some embodiments, FTV 591 is referred to as an FTV-O cell, and FTV 591 is configured to receive an output signal from other clock cells, such as cell 202a in FIG. 2A.

In some embodiments, FTV 591 is referred to as an FTV-I cell, and FTV 591 is configured to output an input signal to other clock cells, such as cell 202a in FIG. 2B.

In some embodiments, the FTV 591 is configured to send one or more signals to an adjacent cell. In some embodiments, the FTV 591 is configured to receive one or more signals from an adjacent cell, such as cell 202a in FIG. 2A. In some embodiments, the FTV 591 is configured to send or receive one or more clock signals, such as at least one of clock signal CLK or CLK3 of FIG. 1, or at least one of inverted clock signal CLK2 of FIG. 1, such as cell 202a in FIG. 2B. In some embodiments, the FTV 591 is configured to send or receive one or more supply voltages or reference supply voltages.

In some embodiments, by merging contacts 306a and 306b into a single contact (e.g., contact 506a), the set of contacts 506 has increased area and/or volume thereby lowering the resistance of the set of contacts 506 compared to other approaches.

In some embodiments, by merging contacts 306a and 306b into a single contact (e.g., contact 506a), the set of contacts 506 has increased area and/or volume thereby increasing the capacitance of the set of contacts 506 compared to other approaches.

In some embodiments, integrated circuit 500 is configured to achieve one or more benefits described herein including the details discussed herein.

Other configurations, arrangements on other levels or quantities of elements in integrated circuit 500 are within the scope of the present disclosure.

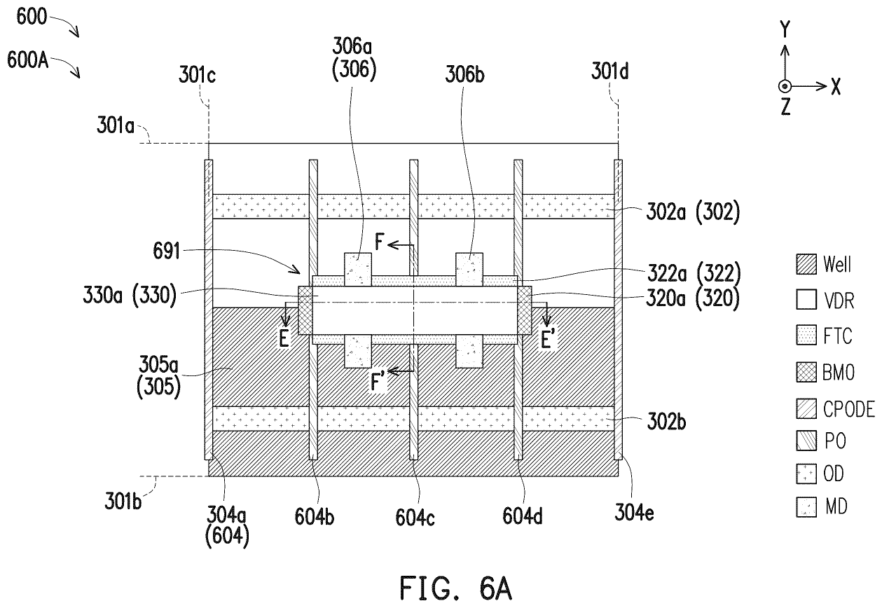

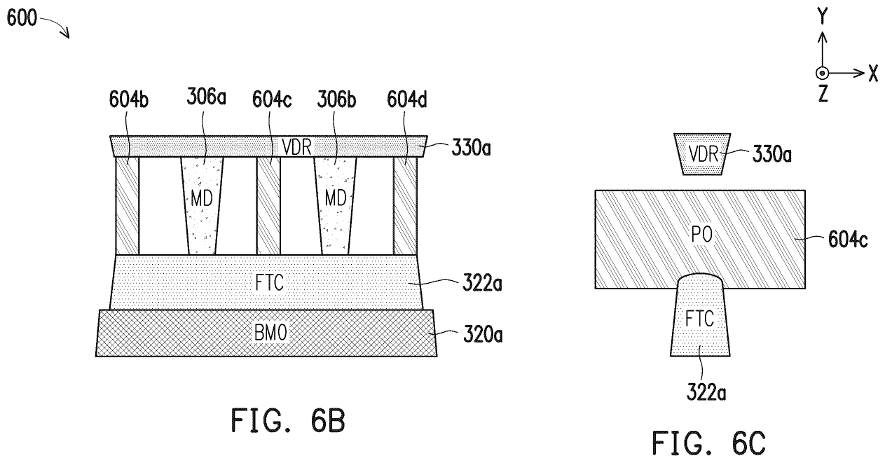

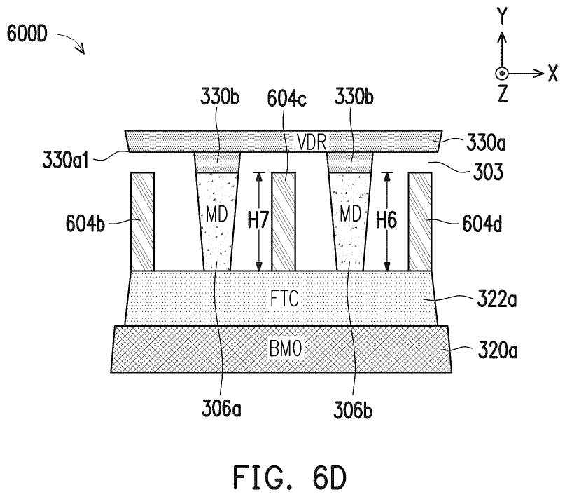

FIG. 6A is a top view of integrated circuit 600, in accordance with some embodiments.

FIGS. 6B-6C are corresponding cross-sectional views of integrated circuit 600, in accordance with some embodiments.

FIG. 6D is a cross-sectional view of integrated circuit 600D, in accordance with some embodiments.

FIG. 6B is a cross-sectional view of integrated circuit 600 as intersected by plane E-E′, in accordance with some embodiments. FIG. 6C is a cross-sectional view of integrated circuit 600 as intersected by plane F-F′, in accordance with some embodiments.

Integrated circuit 600 is an embodiment of at least one of cell 204a, 204b, 204c, 206a, 206b or 206c, and similar detailed description is omitted.

FIG. 6A is a top view of integrated circuit 600, in accordance with some embodiments.

Integrated circuit 600 is manufactured by a corresponding layout design similar to integrated circuit 600.

Integrated circuit 600 is a variation of integrated circuit 300 (FIGS. 3A-3C). In comparison with integrated circuit 300 of FIGS. 3A-3C, a set of gates 604 of integrated circuit 600 replaces the set of gates 304, and similar detailed description is therefore omitted. In comparison with integrated circuit 300 of FIGS. 3A-3C, an FTV 691 of integrated circuit 600 replaces the FTV 391, and similar detailed description is therefore omitted.

Integrated circuit 600 includes at least the cell 301, the substrate 390, the set of active regions 302, the well 305, the insulating region 303, the set of gates 604, the set of contacts 306, the set of conductors 320, the set of conductors 322, and the set of conductors 330.

The set of gates 604 includes at least gate 304a, 604b, 604c, 604d, or 304e. In comparison with integrated circuit 300 of FIGS. 3A-3C, gate 604b of the set of gates 604 replaces gates 304b1 and 304b2 of the set of gates 304, gate 604c of the set of gates 604 replaces gates 304c1 and 304c2 of the set of gates 304, and gate 604d of the set of gates 604 replaces gates 304d1 and 304d2 of the set of gates 304, and similar detailed description is therefore omitted.

In comparison with integrated circuit 300 of FIGS. 3A-3C, gates 304b1 and 304b2 of the set of gates 304 are merged into a single gate (e.g., gate 604b of the set of gates 604), gates 304c1 and 304c2 of the set of gates 304 are merged into a single gate (e.g., gate 604c of the set of gates 604), and gates 304d1 and 304d2 of the set of gates 304 are merged into a single gate (e.g., gate 604d of the set of gates 604), and similar detailed description is therefore omitted.

In some embodiments, at least one of gates 604b, 604c or 604d overlaps at least one of the active region 302a, active region 302b, conductor 322a or conductor 320a. In some embodiments, conductor 330a overlaps at least one of gates 604b, 604c or 604d.

In some embodiments, at least one of gates 604b, 604c or 604d is between conductor 322a and conductor 330a.

In some embodiments, at least one of gates 604b, 604c or 604d alternates with at least one of contacts 306a or 306b in the first direction X.

In some embodiments, the set of gates 604 extend in the second direction Y to at least the cell boundary 301a or 301b. In some embodiments, the gates 604b, 604c and 604d of the set of gates 604 extend in the second direction Y to at least the cell boundary 301a or 301b.

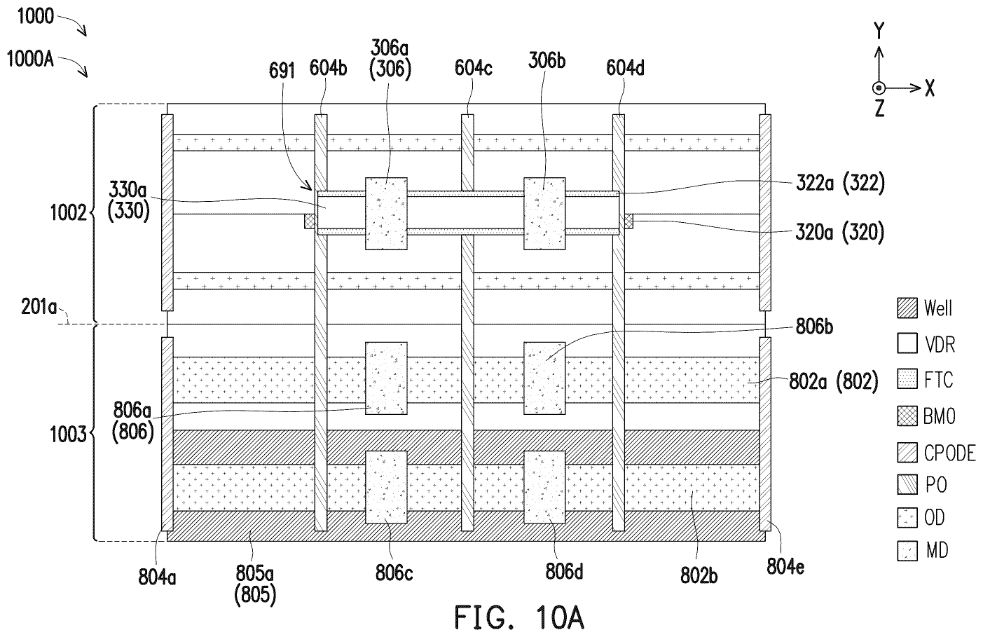

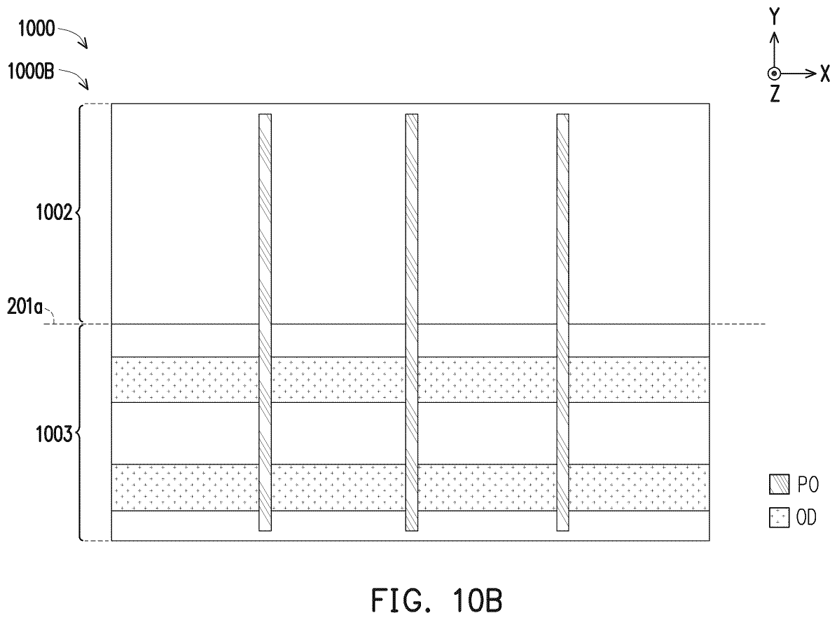

In some embodiments, the set of gates 604 overlap the cell boundary 301a or 301b to a corresponding adjacent cell. In some embodiments, by overlapping the cell boundary 301a or 301b to the corresponding adjacent cell, the set of gates 604 is configured to receive an output signal from the FTV 691 (e.g., as shown in FIGS. 10A-10B), and is configured to output the output signal to the corresponding adjacent cell (e.g., as shown in FIGS. 10A-10B).

In some embodiments, the gates 604b, 604c and 604d of the set of gates 604 overlap the cell boundary 301a or 301b to the corresponding adjacent cell. In some embodiments, by overlapping the cell boundary 301a or 301b to an adjacent cell, the gates 604b, 604c and 604d of the set of gates 604 are configured to receive one or more output signals from the FTV 691 (e.g., as shown in FIGS. 10A-10B), and is configured to output the output signal to an adjacent cell (e.g., as shown in FIGS. 10A-10B).

In some embodiments, the set of gates 604 overlap the cell boundary 301b to another adjacent cell. In some embodiments, the set of gates 604 overlap the cell boundaries 301a and 301b to corresponding adjacent cells.

In some embodiments, at least one of the set of gates 304 or 604 has a height H7 in the second direction Y. In some embodiments, at least one of the set of contacts 306, 406 or 506 has a height H6 in the second direction Y. In some embodiments, the height H6 is greater than the height H7 as shown in FIG. 6B. In some embodiments, when the height H6 is greater than the height H7 as shown in FIG. 6B, then a bottom surface 330al of the conductor 330a is substantially uniform in the first direction X. In some embodiments, when the height H6 is equal to the height H7 as shown in FIG. 6D, then the bottom surface 330al of the conductor 330a is not substantially uniform in the first direction X, and the conductor 330a includes one or more conductive protrusions 330b that extend in the second direction Y. In some embodiments, the one or more conductive protrusions 330b that extend in the second direction Y are in direct contact with the set of contacts 306, thereby providing an electrical connection between the conductor 330a and the set of contacts 306. In some embodiments, the insulating region 303 is between at least a top surface of a gate of the set of gates 604 and the bottom surface 330al of the conductor 330a.

Other configurations, arrangements on other levels or quantities of patterns in the set of gates 604 are within the scope of the present disclosure.

FTV 691 includes the set of contacts 306, the set of conductors 320 and the set of conductors 322.

In some embodiments, the FTV 691 extends from the front-side 390a of the substrate 390 to the back-side 390b of the substrate 390 and vice versa. In some embodiments, FTV 691 is configured to route signals from the front-side 390a of the substrate 390 to the back-side 390b of the substrate 390 and vice versa.

In some embodiments, FTV 691 is referred to as an FTV-I cell, and FTV 691 is configured to output an input signal to other clock cells, such as cell 202a in FIG. 2B.

In some embodiments, the FTV 691 is configured to send one or more signals to an adjacent cell. In some embodiments, the FTV 691 is configured to send one or more clock signals, such as at least one of clock signal CLK or CLK3 of FIG. 1, or at least one of inverted clock signal CLK2 of FIG. 1, to a cell, such as cell 202a in FIG. 2B. In some embodiments, the FTV 691 is configured to send one or more supply voltages or reference supply voltages.

Other configurations, arrangements on other levels or quantities of elements in integrated circuit 600 are within the scope of the present disclosure.

FIG. 6D is a cross-sectional view of integrated circuit 600D, in accordance with some embodiments.

Integrated circuit 600D is a variation of integrated circuit 600 (FIGS. 6A-6C). In comparison with integrated circuit 600 of FIGS. 6A-6C, the height H6 of the set of contacts 306 is equal to the height H7 of the set of gates 604, and similar detailed description is therefore omitted.

In some embodiments, when the height H6 is equal to the height H7 as shown in FIG. 6D, then the bottom surface 330al of the conductor 330a is not substantially uniform in the first direction X, and the conductor 330a includes one or more conductive protrusions 330b that extend in the second direction Y. In some embodiments, the one or more conductive protrusions 330b that extend in the second direction Y are in direct contact with the set of contacts 306, thereby providing an electrical connection between the conductor 330a and the set of contacts 306. In some embodiments, the insulating region 303 is between at least a top surface of a gate of the set of gates 604 and the bottom surface 330al of the conductor 330a.

Other configurations, arrangements on other levels or quantities of elements in integrated circuit 600D are within the scope of the present disclosure.

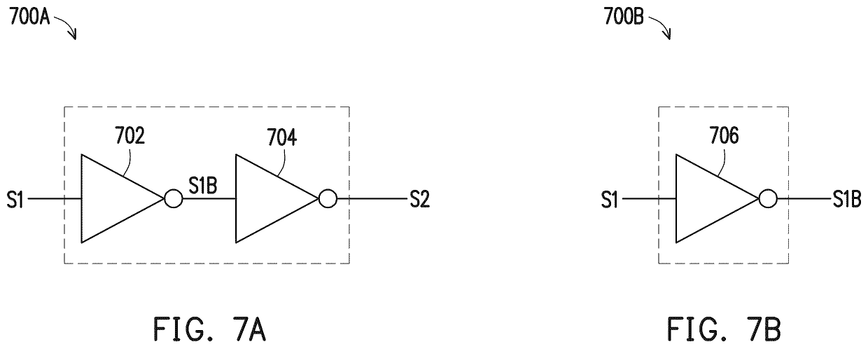

FIG. 7A is a top view of integrated circuit 700A, in accordance with some embodiments.

In some embodiments, integrated circuit 700A is an embodiment of at least one of buffer B1, B2, B3, B4 or B5 in FIG. 1, and similar detailed description is omitted.

In some embodiments, integrated circuit 700A is an embodiment of cell 202a, and similar detailed description is omitted.

Integrated circuit 700A includes an inverter 702 and an inverter 704.

In some embodiments, integrated circuit 700A includes an even number of inverters, such as inverters 702 and 704.

Inverter 702 is configured to generate an inverted signal S1B in response to a signal S1. In some embodiments, the signal S1 is inverted from the inverted signal S1B. An input terminal of inverter 702 is configured to receive the signal S1. An output terminal of inverter 702 is coupled to an input terminal of inverter 704, and is configured to output the inverted signal S1B.

Inverter 704 is configured to generate the signal S2 in response to the inverted signal S1B. In some embodiments, the inverted signal S1B is inverted from the signal S2. An input terminal of inverter 704 is coupled to the output terminal of inverter 702, and is configured to receive the inverted signal S1B. An output terminal of inverter 704 is configured to output the signal S2.

In some embodiments, the signal S2 is a delayed version of signal S1.

Other configurations, other circuit elements or numbers of inverters in integrated circuit 700A are within the scope of the present disclosure.

FIG. 7B is a top view of integrated circuit 700B, in accordance with some embodiments.

In some embodiments, integrated circuit 700B is an embodiment of at least one of inverter I1, I2 or I3 in FIG. 1, and similar detailed description is omitted.

In some embodiments, integrated circuit 700A is an embodiment of cell 202a, and similar detailed description is omitted.

Integrated circuit 700A includes an inverter 706.

Inverter 706 is configured to generate the inverted signal S1B in response to the signal S1. An input terminal of inverter 706 is configured to receive the signal S1. An output terminal of inverter 706 is configured to output the inverted signal S1B.

Other configurations, other circuit elements or numbers of inverters in integrated circuit 700B are within the scope of the present disclosure.

FIG. 8A is a top view of integrated circuit 800, in accordance with some embodiments.

FIG. 8B is a top view of a portion 800B of integrated circuit 800, in accordance with some embodiments.

Integrated circuit 800 includes one or more features of the OD level, the POLY level, the MD level, the BM0 level, the FTC level, the VDR level, the M0 level, the V0 level and the M1 level.

Portion 800B includes one or more features of integrated circuit 800 of the MD level, the M0 level, the V0 level and the M1 level.

In some embodiments, integrated circuit 800 is an embodiment of at least one of integrated circuit 200A or 200B, and similar detailed description is omitted.

Integrated circuit 800 includes a cell 802 and a cell 803.

In some embodiments, cell 802 is an embodiment of at least one of cell 204a or 206a, and similar detailed description is omitted.

In some embodiments, cell 802 is integrated circuit 300 of FIGS. 3A-3C, and similar detailed description is omitted.

In some embodiments, cell 803 is an embodiment of cell 202a, and similar detailed description is omitted.

In some embodiments, cell 803 is an embodiment of one or more buffer circuits, such as integrated circuit 700A of FIG. 7A or one or more inverters, such as integrated circuit 700B of FIG. 7B, and similar detailed description is omitted.

Cell 802 and cell 803 are adjacent to each other along cell boundary 201a.

Cell 803 includes one or more active regions 802a or 802b (collectively referred to as a “set of active regions 802”) extending in the first direction X.

The set of active regions 802 is embedded in the substrate 390 or a set of wells 805.

The substrate 390 further includes the set of wells 805. In some embodiments, the set of wells 805 is similar to the set of wells 305, and similar detailed description is omitted.

The set of wells 805 includes a well 805a. In some embodiments, the well 805a of the set of wells 805 is similar to the well 305a of the set of wells 305, and similar detailed description is omitted.

In some embodiments, the set of active regions 802 is similar to the set of active regions 302, and similar detailed description is omitted.

Active region 802a is embedded in the substrate 390, and active region 802b is embedded in the well 805a.

In some embodiments, active region 802b is an n-type dopant impurity, the well 805 is a P-well, and active region 802b corresponds to N-type transistors, and active region 802a corresponds to P-type transistors.

In some embodiments, active region 802b is a p-type dopant impurity, the well 805 is an N-well, and active region 802b corresponds to P-type transistors, and active region 802a corresponds to N-type transistors.

Active regions 802a, 802b of the set of active regions 802 are separated from one another in the second direction Y. In some embodiments, the set of active regions 802 are located on the front-side 390a of at least integrated circuit 300-600 and 800-1300.

In some embodiments, the set of active regions 802 is manufactured by a set of active region layout patterns similar to the set of active regions 802, and similar detailed description will not be described for brevity. In some embodiments, active regions 802a, 802b of the set of active regions 802 are manufactured by corresponding active region layout patterns similar to active regions 802a, 802b of the set of active regions 802 of integrated circuit 300-600 and 800-1300.

In some embodiments, active region 802a is source and drain regions of PMOS transistors of integrated circuits 300-600 and 800-1300, and active region 802b is source and drain regions of NMOS transistors of integrated circuits 300-600 and 800-1300.

In some embodiments, active region 802a is source and drain regions of NMOS transistors of integrated circuits 300-600 and 800-1300, and active region 802b is source and drain regions of PMOS transistors of integrated circuits 300-600 and 800-1300.

In some embodiments, the set of active regions 802 is located on the first level.

In some embodiments, active region 802a is source and drain regions of one or more n-type CFET, n-type finFET transistors, n-type nanosheet transistors or n-type nanowire transistors, and active region layout pattern 802b is source and drain regions of one or more p-type CFET, p-type finFET transistors, p-type nanosheet transistors or p-type nanowire transistors.

In some embodiments, active region 802a is source and drain regions of one or more p-type CFET, p-type finFET transistors, p-type nanosheet transistors or p-type nanowire transistors, and active region layout pattern 802b is source and drain regions of one or more n-type CFET, n-type finFET transistors, n-type nanosheet transistors or n-type nanowire transistors.

Other numbers of active regions in the set of active regions 802 are within the scope of the present disclosure.

Other configurations, arrangements on other levels or quantities of patterns in the set of active regions 802 are within the scope of the present disclosure.

Cell 803 further includes the insulating region 303 (described above).

Other configurations, arrangements on other layout levels or other numbers of portions in insulating region 303 are within the scope of the present disclosure.

Cell 803 further includes one or more gates 804a, 804b, 804c, 804e or 804e (collectively referred to as a “set of gates 804”) extending in the second direction Y. Each of the gates of the set of gates 804 is separated from an adjacent gate of the set of gates 804 in the first direction X by a first pitch (not labelled).

In some embodiments, the set of gates 804 is similar to the set of gates 304, and similar detailed description is omitted.

The set of gates 804 overlaps the set of active regions 802.

The set of gates 804 is manufactured by a corresponding set of gate patterns similar to the set of gates 804, and similar detailed description will not be described for brevity. In some embodiments, each gate 804a, 804b, 804c, 804e or 804e of the set of gates 804 is manufactured by a corresponding gate pattern similar to corresponding gate 804a, 804b, 804c, 804e or 804e, and similar detailed description will not be described for brevity.

In some embodiments, at least gate 804b, 804c or 804d is a corresponding gate of a corresponding NMOS transistor and a corresponding PMOS transistor.

In some embodiments, at least one of gates 804a or 804e is a corresponding dummy gate or CPODE. In some embodiments, at least gate 804a or 804e corresponds to a dummy gate.

In some embodiments, at least one of gate 804a, 804b, 804c, 804e or 804e corresponds to a dummy gate.

The set of gates 804 is above the set of active regions 802. The set of gates 804 is positioned on the second level.

In some embodiments, the POLY level is above the OD level.

Other configurations, arrangements on other levels or quantities of patterns in the set of gates 804 are within the scope of the present disclosure.

Cell 803 further includes one or more contacts 806a, 806b, 806c or 806d (collectively referred to as a “set of contacts 806”) extending in the second direction Y.

In some embodiments, the set of contacts 806 is similar to the set of contacts 306, and similar detailed description is omitted.

Each of the contacts of the set of contacts 806 is separated from an adjacent contact pattern of the set of contacts 806 in the first direction X.

The set of contacts 806 is manufactured by a corresponding set of contact patterns similar to the set of contacts 806, and similar detailed description will not be described for brevity. In some embodiments, each contact 806a, 806b, 806c or 806d of the set of contacts 806 is manufactured by a corresponding contact pattern similar to corresponding contact 806a, 806b, 806c or 806d of the set of contacts 806, and similar detailed description will not be described for brevity.

In some embodiments, the set of contacts 806 is also referred to as a set of MD conductors.

In some embodiments, at least one of contact 806a, 806b, 806c or 806d of the set of contacts 806 is a corresponding source or drain terminal of one of the NMOS or PMOS transistors of integrated circuit 300-600 and 800-1300.

In some embodiments, the set of contacts 806 overlap the set of active regions 802. The set of contacts is located on the third level.

Other configurations, arrangements on other levels or quantities of patterns in the set of contacts 806 are within the scope of the present disclosure.

In some embodiments, cell 802 is integrated circuit 300 of FIGS. 3A-3C, and similar detailed description is omitted.

Cell 802 includes FTV 391 of FIG. 3A, and similar detailed description is omitted.

Integrated circuit 800 further includes one or more conductors 840a, 840b, 840c (collectively referred to as a “set of conductors 840”) extending in the first direction X.

Each conductor in the set of conductors 840 is separated from another conductor in the set of conductors 840 in the second direction Y.

The set of conductors 840 overlaps at least one of the set of active regions 802, the set of conductors 330, the set of conductors 322, the set of conductors 320, the set of contacts 306, the set of contacts 806 or the set of gates 804.

Conductor 840a overlaps at least one of the set of conductors 330, the set of conductors 322, the set of conductors 320 or the set of contacts 306.

Conductor 840b overlaps at least one of active region 802a, contact 806a, contact 806b, gate 804b, gate 804c or gate 804d.

Conductor 840c overlaps at least one of active region 802b, contact 806c, contact 806d, gate 804b, gate 804c or gate 804d.

In some embodiments, the set of conductors 840 is manufactured by a corresponding set of conductive feature patterns similar to the set of conductors 840.

In some embodiments, conductors 840a, 840b, 840c are manufactured by a corresponding conductive feature pattern similar to corresponding conductor 840a, 840b, 840c.

In some embodiments, at least one conductor of the set of conductors 840 is located on the front-side 303a of integrated circuits 300-600 and 800-1300.

In some embodiments, the set of conductors 840 is located on a seventh level. In some embodiments, the seventh level is different from at least one of the first level, the second level, the third level, the fourth level, the fifth level or the sixth level. In some embodiments, the seventh level corresponds to the M0 level of one or more of integrated circuit 800 or integrated circuits 300-600 and 800-1300. In some embodiments, the M0 level is above the OD level, the POLY level, the MD level, the VDR level, the BM0 level or the FTC level. In some embodiments, the M0 level is below one or more of the V0 level or the M1 level.

In some embodiments, the set of conductors 840 correspond to 3 M0 routing tracks. Other numbers of M0 routing tracks are within the scope of the present disclosure.

Other configurations, arrangements on other levels or quantities of conductors in the set of conductors 840 are within the scope of the present disclosure.

Other M0 track assignments are within the scope of the present disclosure.

Integrated circuit 800 further includes one or more conductors 850a, 850b (collectively referred to as a “set of conductors 850”) extending in the second direction Y.

Each conductor in the set of conductors 850 is separated from another conductor in the set of conductors 850 in the first direction X.

The set of conductors 850 overlaps at least one of the set of conductors 840, the set of vias 842, the set of active regions 302, the set of active regions 802, the set of conductors 330, the set of conductors 322, the set of conductors 320, the set of contacts 306 or the set of contacts 806.

In some embodiments, the set of conductors 850 is manufactured by a corresponding set of conductive feature patterns similar to the set of conductors 850.

In some embodiments, conductors 850a, 850b are manufactured by a corresponding conductive feature pattern similar to corresponding conductor 850a, 850b.

In some embodiments, at least one conductor of the set of conductors 850 is located on the front-side 303a of integrated circuits 300-600 and 800-1300.

In some embodiments, the set of conductors 850 is located on an eighth level. In some embodiments, the eighth level is different from at least one of the first level, the second level, the third level, the fourth level, the fifth level, the sixth level or the seventh level. In some embodiments, the eighth level corresponds to the M1 level of one or more of integrated circuit 800 or 1100-1300. In some embodiments, the M1 level is above the OD level, the POLY level, the MD level, the VDR level, the BM0 level, the FTC level, the M0 level or the V0 level.

In some embodiments, the set of conductors 850 corresponds to 2 M1 routing tracks. Other numbers of M1 routing tracks are within the scope of the present disclosure.

In some embodiments, the set of conductors 850 overlap the cell boundary 301a to cell 803. In some embodiments, by overlapping the cell boundary 301a to cell 803, the set of conductors 850 is configured to send/receive an output signal to/from the cell 803, and are referred to as a set of M1 local interconnects (M1-LIs).

In some embodiments, the conductors 850a and 850b of the set of conductors 850 overlap the cell boundary 301a to cell 803. In some embodiments, by overlapping the cell boundary 301a to cell 803, the conductors 850a and 850b of the set of conductors 850 are configured to send/receive one or more output signals to/from cell 803.

In some embodiments, the set of conductors 850 overlap the cell boundary 201b to another adjacent cell.

In some embodiments, a number of M1 fingers or tracks in the set of conductors 850 is determined based on a ratio R1 in formula 1.

The ratio R1 of a number of M1 fingers to a number of CPP is expressed in formula 1.

$$R 1 = Number of M 1 fingers / Number of CPP \qquad ( 1 )$$

Where the number of M1 fingers is a number of metal 1 fingers or tracks in integrated circuit 800, and the number of CPP is a number of center poly pitch (CPP) in integrated circuit 800.

In some embodiments, the ratio R1 is less than or equal to 10%, and greater than or equal to 35%, as expressed by formula 2.

$$10 \% \leq R 1 \leq 35 \% \qquad ( 2 )$$

Other ranges or values for ratio R1 are within the scope of the present disclosure.

In some embodiments, a number of M0 fingers or tracks in the set of conductors 840 is determined based on a ratio R2 in formula 3.

$$R 2 = Number of M 0 fingers / Height of Clock cell \qquad ( 3 )$$

Where the number of M0 fingers or tracks is a number of metal 0 fingers or tracks in integrated circuit 800, and the height of the clock cell is the height of the clock cell in the second direction Y in integrated circuit 800.

In some embodiments, the ratio R2 is greater than or equal to 1, as expressed by formula 4.

$$R 2 \geq 1 \qquad ( 4 )$$

Other ranges or values for ratio R2 are within the scope of the present disclosure.

For example, formula 2 states that a ratio of a number of M0 fingers to a height of the clock cell should be greater than or equal to 1.

In some embodiments, the height of a clock cell with a single-height is 1. In some embodiments, the height of a clock cell with a single-height is 2. In some embodiments, the height of a clock cell with a triple-height is 3.

In some embodiments, if the ratio R1 is greater than or equal to 10% and less than or equal to 35%, then the resistance of the set of gates 304 and/or the resistance of the set of gates 804 does not cause an increase in the resistance of one or more FTVs (e.g., FTV 391), thus not increasing the resistance of the clock tree or not increasing the clock cell delay, and not reducing the performance of the clock cells and clock tree compared to other approaches.

In some embodiments, if the ratio R1 is less than 10% or greater than 35%, then the resistance of the set of gates 304 and/or the resistance of the set of gates 804 causes an increase in the resistance of one or more FTVs (e.g., FTV 391), thus increasing the resistance of the clock tree or increasing the clock cell delay, and reducing the performance of the clock cells and clock tree compared to other approaches.

In some embodiments, if the ratio R2 is greater than or equal to 1, then the resistance of the set of gates 304 and/or the resistance of the set of gates 804 does not cause an increase in the resistance of one or more FTVs (e.g., FTV 391), thus not increasing the resistance of the clock tree or not increasing the clock cell delay, and not reducing the performance of the clock cells and clock tree compared to other approaches.

In some embodiments, if the ratio R2 is less than 1, then the resistance of the set of gates 304 and/or the resistance of the set of gates 804 causes an increase in the resistance of one or more FTVs (e.g., FTV 391), thus increasing the resistance of the clock tree or increasing the clock cell delay, and reducing the performance of the clock cells and clock tree compared to other approaches.

In some embodiments, by satisfying formulas 1 and 2, a number of conductors in the set of conductors 850 is specified while ensuring that the gate resistance of the set of gates 304 or 804 does not become too large thereby reducing the performance of integrated circuit 800.

In some embodiments, by satisfying formulas 3 and 4, a number of conductors in the set of conductors 840 is specified while ensuring that the gate resistance of the set of gates 304 or 804 does not become too large thereby reducing the performance of integrated circuit 800.

Other configurations, arrangements on other levels or quantities of conductors in the set of conductors 850 are within the scope of the present disclosure.

Integrated circuit 800 further includes one or more vias 842a, 842b, 842c, 842d, 842e, 842f (collectively referred to as a “set of vias 842”).

In some embodiments, the set of vias 842 is manufactured by a corresponding set of via patterns similar to the set of vias 842.

In some embodiments, vias 842a, 842b, 842c, 842d, 842e, 842f of the set of vias 842 are manufacture by corresponding via patterns similar to vias 842a, 842b, 842c, 842d, 842e, 842f of the set of vias 842.

In some embodiments, the set of vias 842 is between the set of conductors 840 and the set of conductors 850.

In some embodiments, the set of vias 842 electrically couples the set of conductors 840 and the set of conductors 850 together.

Via 842a is between conductor 840a and conductor 850a.

Via 842b is between conductor 840a and conductor 850b.

Via 842c is between conductor 840b and conductor 850a.

Via 842d is between conductor 840b and conductor 850b.

Via 842e is between conductor 840c and conductor 850a.

Via 842f is between conductor 840c and conductor 850b.

The set of vias 842 is positioned at a via over M0 (V0) level of one or more of integrated circuit 800 or 1100-1300. In some embodiments, the V0 level is above the OD level, the POLY level, the MD level, the VDR level, the BM0 level, the FTC level, the M0 level or the V0 level. In some embodiments, the V0 level is below the M1 level. In some embodiments, the V0 level is between the M0 level and the M1 level. In some embodiments, the V0 level is between the seventh level and the eighth level. Other levels are within the scope of the present disclosure.

Other configurations, arrangements on other levels or quantities of vias in at least set of vias 842 are within the scope of the present disclosure.

In some embodiments, at least one of the set of conductors 840, the set of conductors 850 or the set of vias 842 is part of at least one of cell 802 or cell 803.

In some embodiments, cell 802 includes FTV 391.

In some embodiments, FTV 391 is referred to as an FTV-O cell, and FTV 391 is configured to receive an output signal from a clock cell, such as cell 803.

In some embodiments, FTV 391 is referred to as an FTV-I cell, and FTV 391 is configured to output an input signal to a clock cell, such as cell 803.

In some embodiments, the FTV 391 is configured to send one or more signals to cell 803.

In some embodiments, the FTV 391 is configured to receive one or more signals from cell 803.

In some embodiments, the FTV 391 is configured to send one or more clock signals, such as at least one of clock signal CLK or CLK3 of FIG. 1, or at least one of inverted clock signal CLK2 of FIG. 1, to cell 803.

In some embodiments, the FTV 391 is configured to receive one or more clock signals, such as at least one of clock signal CLK or CLK3 of FIG. 1, or at least one of inverted clock signal CLK2 of FIG. 1, from cell 803.

In some embodiments, the set of conductors 840 and 850 and the set of vias 842 are configured to provide a cell to FTV electrical connection between FTV 391 and cell 803. In some embodiments, by electrically connecting FTV 391 and cell 803 together, the FTV 391 is configured to send/receive an output signal to/from the cell 803 while being located outside of the cell 803, and thus not occupying area within the cell 803.

In some embodiments, by electrically connecting FTV 391 and cell 803 together, the FTV 391 is configured to send/receive an output signal to/from the cell 803 while reducing the resistance and/or capacitance of the FTVs thereby reducing the resistance and/or capacitance of the clock tree by using backside routing compared to other approaches.

In some embodiments, by reducing the resistance and/or capacitance of the clock tree (e.g., integrated circuit 800), integrated circuit 800 has less clock cell delay than other approaches, thereby improving the performance of the clock cells and/or clock trees of integrated circuit 800 compared to other approaches.

Other configurations, arrangements on other levels or quantities of elements in integrated circuit 800 are within the scope of the present disclosure.

FIG. 9A is a top view of integrated circuit 900, in accordance with some embodiments.

FIG. 9B is a top view of a portion 900B of integrated circuit 900, in accordance with some embodiments.

Integrated circuit 900 includes one or more features of the OD level, the POLY level, the MD level, the BM0 level, the FTC level and the VDR level.

Portion 900B includes one or more features of integrated circuit 900 of the OD level and the MD level.

In some embodiments, integrated circuit 900 is an embodiment of at least one of integrated circuit 200A or 200B, and similar detailed description is omitted.

Integrated circuit 900 is a variation of integrated circuit 800 (FIGS. 8A-8B). In comparison with integrated circuit 800 of FIGS. 8A-8B, the set of contacts 406 of integrated circuit 900 replaces the set of contacts 306 and 806, and similar detailed description is therefore omitted.

In comparison with integrated circuit 800 of FIGS. 8A-8B, integrated circuit 900 does not include the set of conductors 840, the set of vias 842 and the set of conductors 850, and similar detailed description is therefore omitted.

In comparison with integrated circuit 800 of FIGS. 8A-8B, the FTV 491 of integrated circuit 900 replaces the FTV 391 of FIGS. 8A-8B, and similar detailed description is therefore omitted.

Integrated circuit 900 includes a cell 902 and a cell 903.

In some embodiments, cell 902 is an embodiment of at least one of cell 204a or 206a, and similar detailed description is omitted.

In some embodiments, cell 902 is integrated circuit 400 of FIG. 4, and similar detailed description is omitted.

In some embodiments, cell 903 is similar to cell 803 of FIG. 8A, and similar detailed description is omitted.

In some embodiments, cell 903 is an embodiment of cell 202a, and similar detailed description is omitted. In some embodiments, cell 903 is an embodiment of one or more buffer circuits, such as integrated circuit 700A of FIG. 7A or one or more inverters, such as integrated circuit 700B of FIG. 7B, and similar detailed description is omitted.

Cell 902 and cell 903 are adjacent to each other along cell boundary 201a.

Cell 903 includes the set of active regions 802, the insulating region 303, the set of gates 804 and the set of wells 805.

Cell 902 includes the set of active regions 302, the insulating region 303, the set of gates 304, the set of contacts 406, the set of wells 305, the set of conductors 320, the set of conductors 322 and the set of conductors 330.

In some embodiments, the set of contacts 406, the set of conductors 320 and the set of conductors 322 are part of FTV 491.

The set of contacts 406 includes at least contact 406a or 406b.

The set of contacts 406 overlap the active regions 302b, 802a and 802b. The contacts 406a and 406b of the set of contacts 406 overlap the active regions 302b, 802a and 802b.

In some embodiments, contacts 406a and 406b of the set of contacts 406 are electrically coupled to at least one of active region 302b, 802a or 802b. In some embodiments, FTV 491 is configured to receive an output signal from at least one of active region 802a or 802b by contacts 406a and 406b.

In some embodiments, the set of contacts 406 overlap the cell boundary 201a into cell 903. In some embodiments, by overlapping the cell boundary 201a into cell 903, the set of contacts 406 is configured to receive an output signal from cell 903, and is referred to as a set of MD local interconnects (MD-LIs).

In some embodiments, the contacts 406a and 406b of the set of contacts 406 overlap the cell boundary 201a into cell 903. In some embodiments, by overlapping the cell boundary 201a into cell 903, the contacts 406a and 406b of the set of contacts 406 are configured to receive one or more output signals from cell 903, and are referred to as a set of MD-LIs.

In some embodiments, the set of contacts 406 overlap another cell boundary (not labelled) to another adjacent cell.

Other configurations, arrangements on other levels or quantities of patterns in the set of contacts 406 are within the scope of the present disclosure.

Other configurations, arrangements on other levels or quantities of elements in at least one of cell 802 or 803 are within the scope of the present disclosure.

In some embodiments, cell 902 includes FTV 491.

In some embodiments, FTV 491 is referred to as an FTV-O cell, and FTV 491 is configured to receive an output signal from other clock cells, such as cell 903.

In some embodiments, the FTV 491 is configured to receive one or more signals from an adjacent cell, such as cell 903.

In some embodiments, the FTV 491 is configured to receive one or more signals from cell 903.

In some embodiments, the FTV 491 is configured to receive one or more clock signals, such as at least one of clock signal CLK or CLK3 of FIG. 1, or at least one of inverted clock signal CLK2 of FIG. 1, from cell 903.

In some embodiments, the set of contacts 406 is configured to provide a cell to FTV electrical connection between FTV 491 and cell 903. In some embodiments, by electrically connecting FTV 491 and cell 903 together, the FTV 491 is configured to receive an output signal from the cell 903 while being located outside of the cell 903, and thus not occupying area within the cell 903.

In some embodiments, by electrically connecting FTV 491 and cell 903 together, the FTV 491 is configured to receive an output signal from the cell 903 while reducing the resistance and/or capacitance of the FTVs thereby reducing the resistance and/or capacitance of the clock tree by using backside routing compared to other approaches.

In some embodiments, by reducing the resistance and/or capacitance of the clock tree (e.g., integrated circuit 900), integrated circuit 900 has less clock cell delay than other approaches, thereby improving the performance of the clock cells and/or clock trees of integrated circuit 900 compared to other approaches.

Other configurations, arrangements on other levels or quantities of elements in integrated circuit 900 are within the scope of the present disclosure.

FIG. 10A is a top view of integrated circuit 1000, in accordance with some embodiments.

FIG. 10B is a top view of a portion 1000B of integrated circuit 1000, in accordance with some embodiments.

Integrated circuit 1000 includes one or more features of the OD level, the POLY level, the MD level, the BM0 level, the FTC level and the VDR level.

Portion 1000B includes one or more features of integrated circuit 1000 of the OD level and the POLY level.

In some embodiments, integrated circuit 1000 is an embodiment of at least one of integrated circuit 200A or 200B, and similar detailed description is omitted.

Integrated circuit 1000 is a variation of integrated circuit 800 (FIGS. 8A-8B). In comparison with integrated circuit 800 of FIGS. 8A-8B, the set of gates 604 of integrated circuit 1000 replaces the set of gates 304 and 804, and similar detailed description is therefore omitted.

In comparison with integrated circuit 800 of FIGS. 8A-8B, integrated circuit 1000 does not include the set of conductors 840, the set of vias 842 and the set of conductors 850, and similar detailed description is therefore omitted.

In comparison with integrated circuit 800 of FIGS. 8A-8B, the FTV 691 of integrated circuit 1000 replaces the FTV 391 of FIGS. 8A-8B, and similar detailed description is therefore omitted.

Integrated circuit 1000 includes a cell 1002 and a cell 1003.

In some embodiments, cell 1002 is an embodiment of at least one of cell 204a or 206a, and similar detailed description is omitted.

In some embodiments, cell 1002 is integrated circuit 600 of FIGS. 6A-6C, and similar detailed description is omitted.

In some embodiments, cell 1003 is similar to cell 803 of FIG. 8A, and similar detailed description is omitted.

In some embodiments, cell 1003 is an embodiment of cell 202a, and similar detailed description is omitted. In some embodiments, cell 1003 is an embodiment of one or more buffer circuits, such as integrated circuit 700A of FIG. 7A or one or more inverters, such as integrated circuit 700B of FIG. 7B, and similar detailed description is omitted.

Cell 1002 and cell 1003 are adjacent to each other along cell boundary 201a.

Cell 1003 includes the set of active regions 802, the insulating region 303, gates 804a and 804b, the set of contacts 806 and the set of wells 805.

Cell 1002 includes the set of active regions 302, the insulating region 303, the set of gates 604, the set of contacts 306, the set of wells 305, the set of conductors 320, the set of conductors 322 and the set of conductors 330.

In some embodiments, the set of contacts 306, the set of conductors 320 and the set of conductors 322 are part of FTV 691.

The set of gates 604 includes at least gate 304a, 604b, 604c, 604d, or 304e.

In some embodiments, at least one of gates 604b, 604c or 604d overlaps at least one of the active region 302b, active region 802a or active region 802b.

In some embodiments, FTV 691 is electrically coupled to one or more transistors in cell 1003 by at least one of gates 604b, 604c or 604d.

In some embodiments, the set of gates 604 overlap the cell boundary 201a into cell 1003. In some embodiments, by overlapping the cell boundary 201a into cell 1003, the set of gates 604 is configured to receive an output signal from the FTV 691, and is configured to output the output signal to cell 1003, and is referred to as a set of POLY local interconnects (POLY-LIs).

In some embodiments, the gates 604b, 604c and 604d of the set of gates 604 overlap the cell boundary 201a into cell 1003. In some embodiments, by overlapping the cell boundary 201a or 301b into cell 1003, the gates 604b, 604c and 604d of the set of gates 604 are configured to receive one or more output signals from the FTV 691, and is configured to output the output signal into cell 1003, and are referred to as a set of POLY-LIs.

In some embodiments, the set of gates 604 overlap another cell boundary (not labelled) to another adjacent cell.

Other configurations, arrangements on other levels or quantities of gates in the set of gates 604 are within the scope of the present disclosure.

Other configurations, arrangements on other levels or quantities of elements in at least one of cell 802 or 803 are within the scope of the present disclosure.

In some embodiments, cell 1002 includes FTV 691.

In some embodiments, FTV 691 is referred to as an FTV-I cell, and FTV 691 is configured to send/output an input signal to other clock cells, such as cell 1003.

In some embodiments, the FTV 691 is configured to send one or more signals to an adjacent cell, such as cell 1003.

In some embodiments, the FTV 691 is configured to send one or more signals to cell 1003.

In some embodiments, the FTV 691 is configured to send one or more clock signals, such as at least one of clock signal CLK or CLK3 of FIG. 1, or at least one of inverted clock signal CLK2 of FIG. 1, to cell 1003.

In some embodiments, the set of gates 604 is configured to provide a cell to FTV electrical connection between FTV 691 and cell 1003. In some embodiments, by electrically connecting FTV 691 and cell 1003 together, the FTV 691 is configured to output an input signal to the cell 1003 while being located outside of the cell 1003, and thus not occupying area within the cell 1003.

In some embodiments, by electrically connecting FTV 691 and cell 1003 together, the FTV 691 is configured to output an input signal to the cell 1003 while reducing the resistance and/or capacitance of the FTVs thereby reducing the resistance and/or capacitance of the clock tree by using backside routing compared to other approaches.

In some embodiments, by reducing the resistance and/or capacitance of the clock tree (e.g., integrated circuit 1000), integrated circuit 1000 has less clock cell delay than other approaches, thereby improving the performance of the clock cells and/or clock trees of integrated circuit 1000 compared to other approaches.

Other configurations, arrangements on other levels or quantities of elements in integrated circuit 1000 are within the scope of the present disclosure.

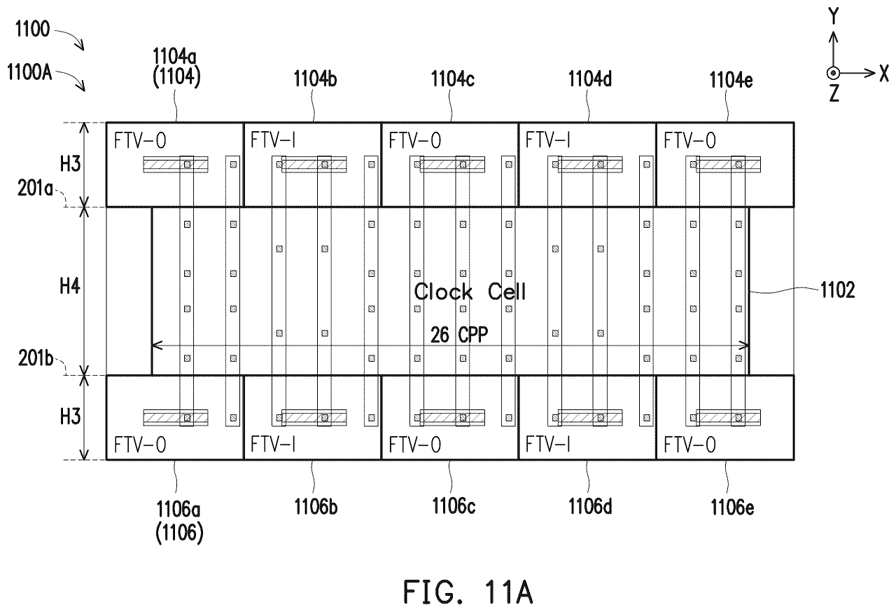

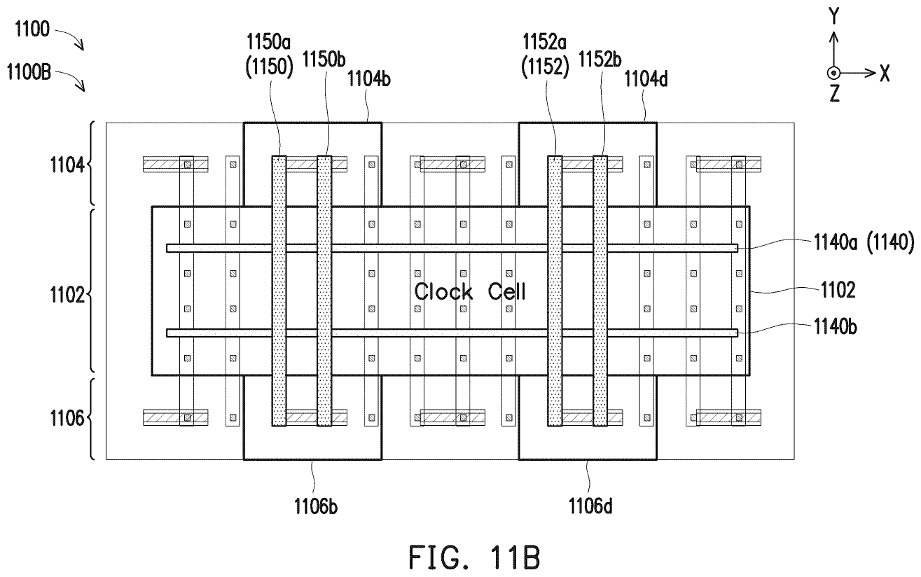

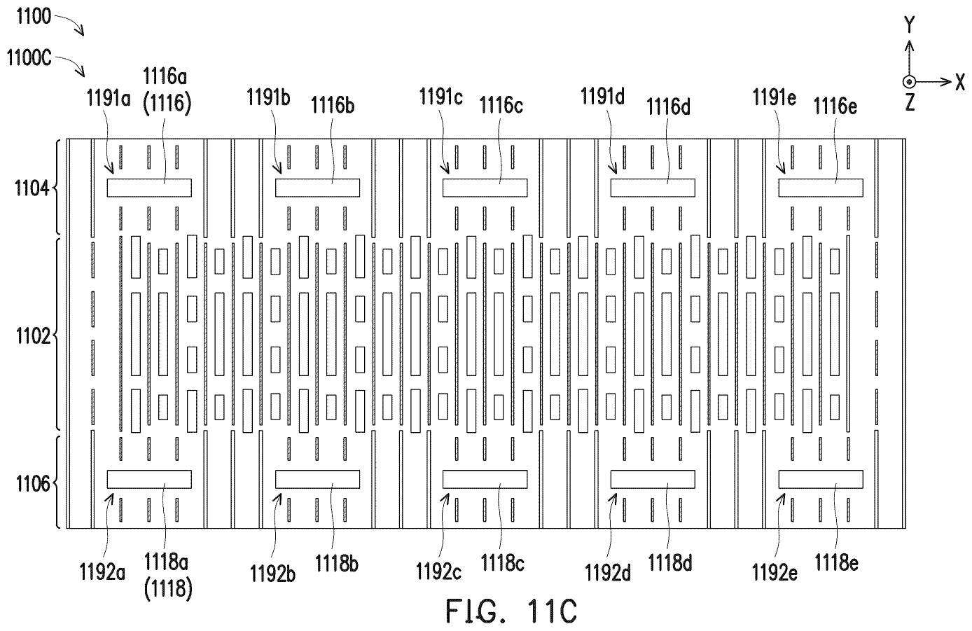

FIG. 11A is a top view of a portion 1100A of an integrated circuit 1100, in accordance with some embodiments.

FIG. 11B is a top view of a portion 1100B of integrated circuit 1100, in accordance with some embodiments.

FIG. 11C is a top view of a portion 1100C of integrated circuit 1100, in accordance with some embodiments.

Integrated circuit 1100 includes one or more features of the OD level, the POLY level, the MD level, the BM0 level, the FTC level, the VDR level, the M0 level, the V0 level and the M1 level.

Portion 1100A includes one or more features of integrated circuit 1100 of the MD level, the V0 level and the M1 level.

Portion 1100B includes one or more features of integrated circuit 1100 of the MD level, the M0 level, the V0 level and the M1 level.

Portion 1100C includes one or more features of integrated circuit 1100 of the POLY level and the MD level.

In some embodiments, integrated circuit 1100 is an embodiment of a portion of at least one of integrated circuit 200G or 200H, and similar detailed description is omitted.

In some embodiments, integrated circuit 1100 is an example of a plurality of FTV cells (e.g., set of FTV cells 1191 and 1192) along cell boundaries 201a and 201b.

Integrated circuit 1100 is a variation of integrated circuit 800 (FIGS. 8A-8B). In comparison with integrated circuit 800 of FIGS. 8A-8B, a set of FTVs 1191 and 1192 of integrated circuit 1100 replaces FTV 391, and similar detailed description is therefore omitted.

In some embodiments, each FTV of the set of FTVs 1191 or 1192 of integrated circuit 1100 is similar to FTV 391 of FIGS. 8A-8B, and similar detailed description is therefore omitted.

Integrated circuit 1100 includes a cell 1102, a set of cells 1104 and a set of cells 1106.

In some embodiments, cell 1102 is similar to cell 803 of FIGS. 8A-8C, and similar detailed description is omitted.

Cell 1102 and the set of cells 1104 are adjacent to each other along cell boundary 201a.

Cell 1102 and the set of cells 1106 are adjacent to each other along cell boundary 201b.

The set of cells 1104 and 1106 have a height H3 in the second direction Y. In some embodiments, at least one of the set of cells 1104 or 1106 is a single height cell.

The cell 1102 has a height H4 in the second direction Y. In some embodiments, cell 1102 is a double height cell.

In some embodiments, the set of cells 1104 and 1104 have a width in the first direction X, that is greater than a width of cell 1102 in the first direction X.

The set of cells 1104 includes one or more of cells 1104a, 1104b, . . . , 1104d or 1104e.

In some embodiments, each cell 1104a, 1104b, . . . , 1104d or 1104e of the set of cells 1104 is similar to cell 802 of FIGS. 8A-8C, and similar detailed description is omitted.

In some embodiments, each cell 1104a, 1104b, . . . , 1104d or 1104e of the set of cells 1104 is an alternating sequence of FTV-O and FTV-I cells similar to cells 204a or 206a of FIGS. 2A-2B, and similar detailed description is omitted.

In some embodiments, each cell 1104a, 1104b, . . . , 1104d or 1104e of the set of cells 1104 includes a corresponding FTV 1191a, 1191b, . . . , 1191d or 1191e of a set of FTVs 1191 that is similar to FTV 591 of FIGS. 5A-5C, and similar detailed description is omitted.

In some embodiments, each FTV 1191a, 1191b, . . . , 1191d or 1191e of the set of FTVs 1191 includes a corresponding contact 1116a, 1116b, . . . , 1116d or 1116e of a set of contacts 1116 that is similar to contacts 506a of the set of contacts 506 of FIG. 5, and similar detailed description is omitted.

The set of cells 1106 includes one or more of cells 1106a, 1106b, . . . , 1106d or 1106e.

In some embodiments, each cell 1106a, 1106b, . . . , 1106d or 1106e of the set of cells 1106 is similar to cell 802 of FIGS. 8A-8C, and similar detailed description is omitted.

In some embodiments, each cell 1106a, 1106b, . . . , 1106d or 1106e of the set of cells 1106 is an alternating sequence of FTV-O and FTV-I cells similar to cells 204a or 206a of FIGS. 2A-2B, and similar detailed description is omitted.

In some embodiments, each cell 1106a, 1106b, . . . , 1106d or 1106e of the set of cells 1106 includes a corresponding FTV 1192a, 1192b, . . . , 1192d or 1192e of a set of FTVs 1192 that is similar to FTV 591 of FIGS. 5A-5C, and similar detailed description is omitted.

In some embodiments, each FTV 1192a, 1192b, . . . , 1192d or 1192e of the set of FTVs 1192 includes a corresponding contact 1118a, 1118b, . . . , 1118d or 1118e of a set of contacts 1118 that is similar to contact 506a of the set of contacts 506 of FIG. 5, and similar detailed description is omitted.

Integrated circuit 1100 further includes a set of conductors 1140, a set of conductors 1150 and a set of conductors 1152.

In some embodiments, the set of conductors 1140 is similar to the set of conductors 840 of FIGS. 8A-8C, and similar detailed description is omitted.

In some embodiments, at least one of the set of conductors 1150 or 1152 is similar to the set of conductors 850 of FIGS. 8A-8C, and similar detailed description is omitted.

The set of conductors 1140 includes one or more of conductors 1140a or 1140b.

In some embodiments, each of conductors 1140a or 1140b of the set of conductors 1140 is similar to corresponding conductor 840a or 840b of the set of conductors 840 of FIGS. 8A-8C, and similar detailed description is omitted.

The set of conductors 1150 includes one or more of conductors 1150a or 1150b.

In some embodiments, each of conductors 1150a or 1150b of the set of conductors 1150 is similar to corresponding conductor 850a or 850b of the set of conductors 850 of FIGS. 8A-8C, and similar detailed description is omitted.

In some embodiments, each of conductors 1152a or 1152b of the set of conductors 1152 is similar to corresponding conductor 850a or 850b of the set of conductors 850 of FIGS. 8A-8C, and similar detailed description is omitted.

In a non-limiting example, formulas 1-4 are applied to integrated circuit 1100. For example, integrated circuit 1100 includes 4 M1 fingers and 2 M0 fingers, and a number of CPPs that is equal to 26 CPPs. Furthermore, in this non-limiting example, the height H4 is equal to 2 since cell 1102 is a double height cell.

In some embodiments, applying formula 1 yields, the Ratio R1 to be equal to 4/26, which is equal to 15.3%. In some embodiments, when the ratio R1 is 15.3%, then ratio R1 is between 10% and 35%, and thereby satisfies formula 2.

In some embodiments, applying formula 3 yields, the Ratio R2 to be equal to 2/2, which is equal to 1. In some embodiments, when the ratio R2 is 1, then ratio R2 is equal to 1, and thereby satisfies formula 4.

In some embodiments, integrated circuit 1100 is configured to achieve one or more benefits described herein including the details discussed herein.

Other configurations, arrangements on other levels or quantities of elements in integrated circuit 1100 are within the scope of the present disclosure.

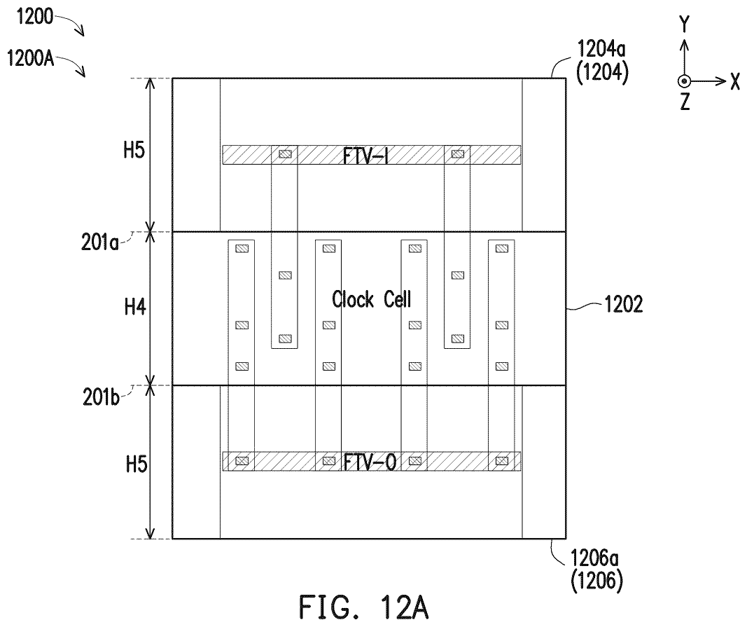

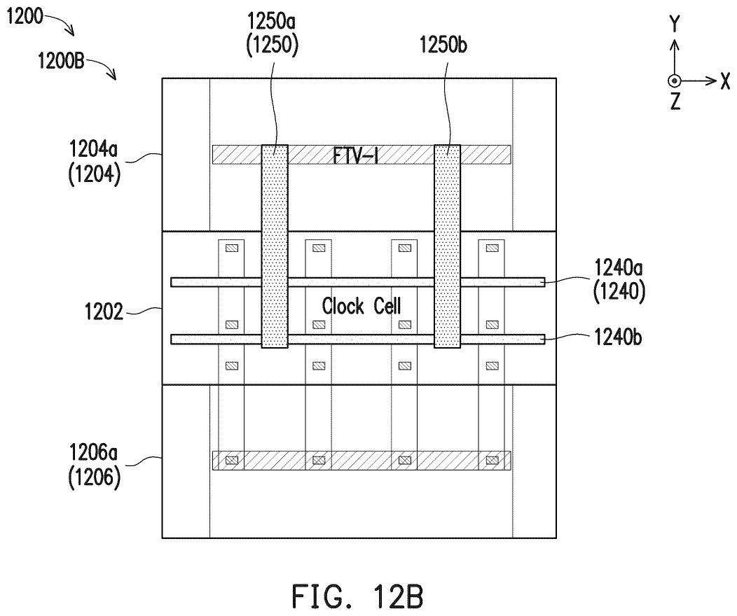

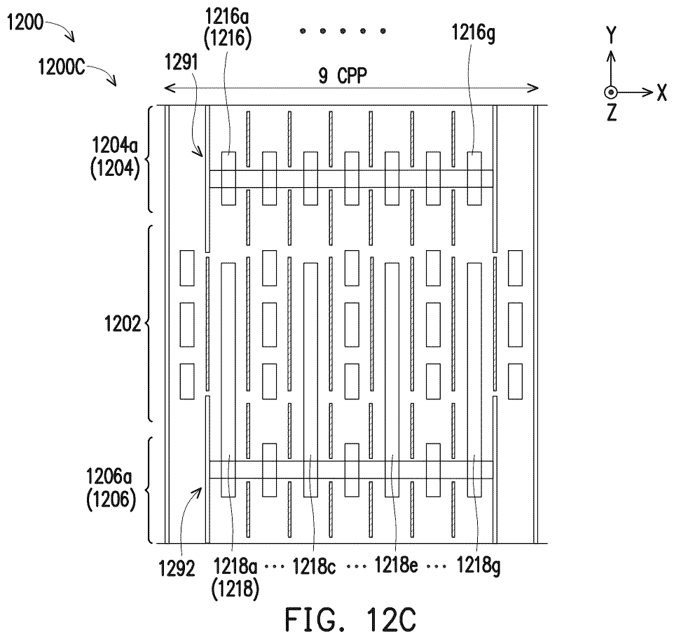

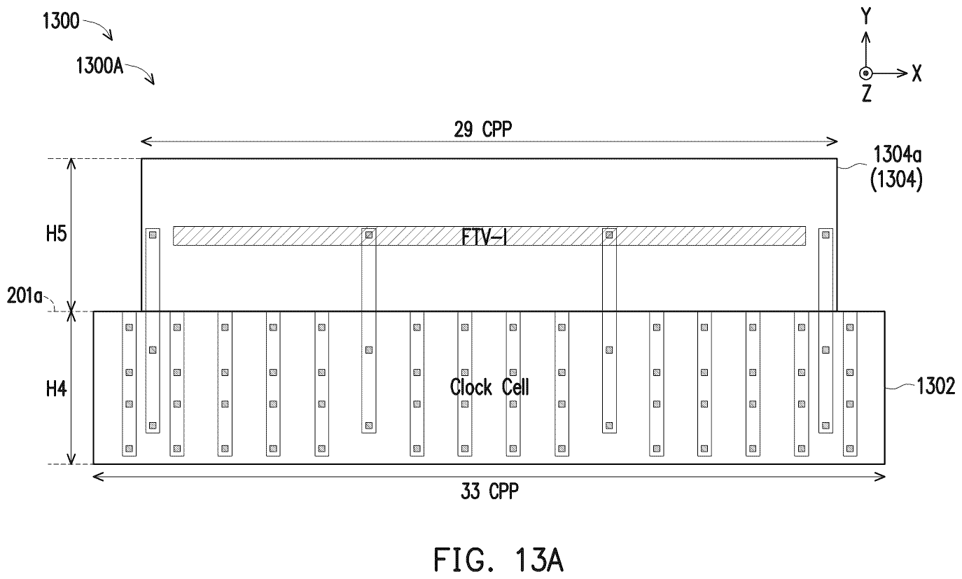

FIG. 12A is a top view of a portion 1200A of an integrated circuit 1200, in accordance with some embodiments.

FIG. 12B is a top view of a portion 1200B of integrated circuit 1200, in accordance with some embodiments.

FIG. 12C is a top view of a portion 1200C of integrated circuit 1200, in accordance with some embodiments.

Integrated circuit 1200 includes one or more features of the OD level, the POLY level, the MD level, the BM0 level, the FTC level, the VDR level, the M0 level, the V0 level and the M1 level.

Portion 1200A includes one or more features of integrated circuit 1200 of the MD level, the V0 level and the M1 level.

Portion 1200B includes one or more features of integrated circuit 1200 of the MD level, the MG level, the V0 level and the M1 level.

Portion 1200C includes one or more features of integrated circuit 1200 of the POLY level, the MD level and the VDR level.

In some embodiments, integrated circuit 1200 is an embodiment of a portion of at least one of integrated circuit 200G or 200H, and similar detailed description is omitted.

In some embodiments, integrated circuit 1200 is an example of FTV cells (e.g., FTV cells 1291 and 1292) along cell boundaries 201a and 201b.

Integrated circuit 1200 is a variation of integrated circuit 800 (FIGS. 8A-8B). In comparison with integrated circuit 800 of FIGS. 8A-8B, FTVs 1291 and 1292 of integrated circuit 1200 replaces FTV 391, and similar detailed description is therefore omitted.

In some embodiments, each FTV of the set of FTVs 1291 or 1292 of integrated circuit 1200 is similar to FTV 391 of FIGS. 8A-8B, and similar detailed description is therefore omitted.

Integrated circuit 1200 includes a cell 1202, a set of cells 1204 and a set of cells 1206.

In some embodiments, cell 1202 is similar to cell 803 of FIGS. 8A-8C, and similar detailed description is omitted.

Cell 1202 and the set of cells 1204 are adjacent to each other along cell boundary 201a.

Cell 1202 and the set of cells 1206 are adjacent to each other along cell boundary 201b.

The set of cells 1204 and 1206 have a height H5 in the second direction Y. In some embodiments, at least one of the set of cells 1204 or 1206 is a double height cell.

The cell 1202 has a height H4 in the second direction Y. In some embodiments, cell 1202 is a double height cell.

In some embodiments, the set of cells 1204 and 1206 have a width in the first direction X, that is equal to a width of cell 1202 in the first direction X.

The set of cells 1204 includes one or more of cell 1204a.

In some embodiments, each cell 1204a of the set of cells 1204 is similar to cell 802 of FIGS. 8A-8C, and similar detailed description is omitted.

In some embodiments, each cell 1204a of the set of cells 1204 includes a corresponding FTV 1291a of a set of FTVs 1291 that is similar to FTV 391 of FIGS. 3A-3C, and similar detailed description is omitted.

In some embodiments, each FTV 1291a of the set of FTVs 1291 includes a corresponding contact 1216a, 1216b, . . . , 1216f or 1216g of a set of contacts 1216 that is similar to contacts 306a, 306b of the set of contacts 306 of FIG. 5, and similar detailed description is omitted.

The set of cells 1206 includes one or more of cell 1206a.

In some embodiments, each cell 1206a of the set of cells 1206 is similar to cell 802 of FIGS. 8A-8C, and similar detailed description is omitted.

In some embodiments, each cell 1206a of the set of cells 1206 includes a corresponding FTV 1292a of a set of FTVs 1292 that is similar to FTV 391 of FIGS. 3A-3C, and similar detailed description is omitted.

In some embodiments, each FTV 1292a of the set of FTVs 1292 includes a corresponding contact 1218a, 1218b, . . . , 1218f or 1218g of a set of contacts 1218 that is similar to contacts 306a, 306b of the set of contacts 306 of FIGS. 3A-3C and similar detailed description is omitted.

Integrated circuit 1200 further includes a set of conductors 1240 and a set of conductors 1250.

In some embodiments, the set of conductors 1240 is similar to the set of conductors 840 of FIGS. 8A-8C, and similar detailed description is omitted.

In some embodiments, the set of conductors 1250 is similar to the set of conductors 850 of FIGS. 8A-8C, and similar detailed description is omitted.

The set of conductors 1240 includes one or more of conductors 1240a or 1240b.

In some embodiments, each of conductors 1240a or 1240b of the set of conductors 1240 is similar to corresponding conductor 840a or 840b of the set of conductors 840 of FIGS. 8A-8C, and similar detailed description is omitted.

The set of conductors 1250 includes one or more of conductors 1250a or 1250b.

In some embodiments, each of conductors 1250a or 1250b of the set of conductors 1250 is similar to corresponding conductor 850a or 850b of the set of conductors 850 of FIGS. 8A-8C, and similar detailed description is omitted.

In a non-limiting example, formulas 1-4 are applied to integrated circuit 1200. For example, integrated circuit 1200 includes 2 M1 fingers and 2 M0 fingers, and a number of CPPs that is equal to 9 CPPs. Furthermore, in this non-limiting example, the height H4 is equal to 2 since cell 1202 is a double height cell.

In some embodiments, applying formula 1 yields, the Ratio R1 to be equal to 2/9, which is equal to 22.2%. In some embodiments, when the ratio R1 is 22.2%, then ratio R1 is between 10% and 35%, and thereby satisfies formula 2.

In some embodiments, applying formula 3 yields, the Ratio R2 to be equal to 2/2, which is equal to 1. In some embodiments, when the ratio R2 is 1, then ratio R2 is equal to 1, and thereby satisfies formula 4.

In some embodiments, integrated circuit 1200 is configured to achieve one or more benefits described herein including the details discussed herein.

Other configurations, arrangements on other levels or quantities of elements in integrated circuit 1200 are within the scope of the present disclosure.

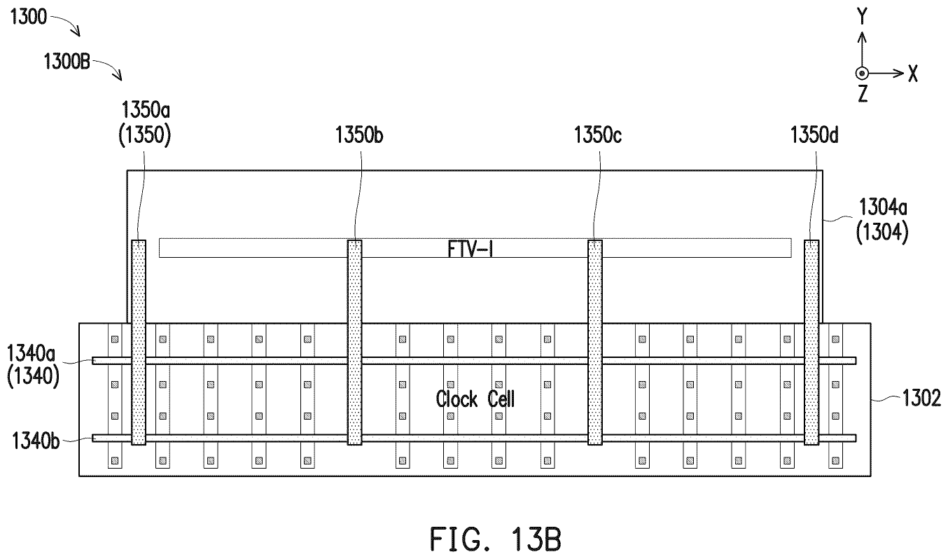

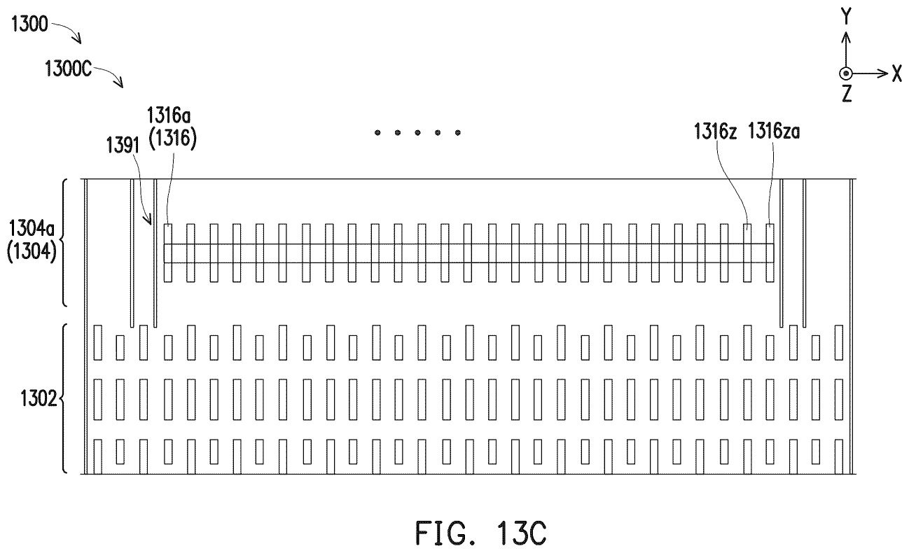

FIG. 13A is a top view of a portion 1300A of an integrated circuit 1300, in accordance with some embodiments.

FIG. 13B is a top view of a portion 1300B of integrated circuit 1300, in accordance with some embodiments.

FIG. 13C is a top view of a portion 1300C of integrated circuit 1300, in accordance with some embodiments.

Integrated circuit 1300 includes one or more features of the OD level, the POLY level, the MD level, the BM0 level, the FTC level, the VDR level, the M0 level, the V0 level and the M1 level.

Portion 1300A includes one or more features of integrated circuit 1300 of the MD level, the V0 level and the M1 level.

Portion 1300B includes one or more features of integrated circuit 1300 of the MD level, the M0 level, the V0 level and the M1 level.

Portion 1300C includes one or more features of integrated circuit 1300 of the POLY level, the MD level and the VDR level.

In some embodiments, integrated circuit 1300 is an embodiment of at least one of integrated circuit 200G or 200H, and similar detailed description is omitted.

In some embodiments, integrated circuit 1300 is an example of an FTV cell (e.g., FTV cell 1391) along cell boundary 201a.

Integrated circuit 1300 is a variation of integrated circuit 800 (FIGS. 8A-8B). In comparison with integrated circuit 800 of FIGS. 8A-8B, FTV 1391 of integrated circuit 1300 replaces FTV 391, and similar detailed description is therefore omitted.

In some embodiments, each FTV of the set of FTVs 1391 of integrated circuit 1300 is similar to FTV 391 of FIGS. 8A-8B, and similar detailed description is therefore omitted.

Integrated circuit 1300 includes a cell 1302 and a set of cells 1304.

In some embodiments, cell 1302 is similar to cell 803 of FIGS. 8A-8C, and similar detailed description is omitted.

Cell 1302 and the set of cells 1304 are adjacent to each other along cell boundary 201a.

The set of cells 1304 has a height H5 in the second direction Y. In some embodiments, at least one cell of the set of cells 1304 is a double height cell.

The cell 1302 has a height H4 in the second direction Y. In some embodiments, cell 1302 is a double height cell.

In some embodiments, the set of cells 1304 has a width in the first direction X, that is less than a width of cell 1302 in the first direction X.

The set of cells 1304 includes one or more of cell 1304a.

In some embodiments, each cell 1304a of the set of cells 1304 is similar to cell 802 of FIGS. 8A-8C, and similar detailed description is omitted.

In some embodiments, each cell 1304a of the set of cells 1304 includes a corresponding FTV 1391a of a set of FTVs 1391 that is similar to FTV 391 of FIGS. 3A-3C, and similar detailed description is omitted.

In some embodiments, FTV 1391a of the set of FTVs 1391 includes a contact 1316a, 1316b, . . . , 1316y, 1316z or 1316za of a set of contacts 1316 that is similar to contacts 306a, 306b of the set of contacts 306 of FIG. 5, and similar detailed description is omitted.

Integrated circuit 1300 further includes a set of conductors 1340 and a set of conductors 1350.

In some embodiments, the set of conductors 1340 is similar to the set of conductors 840 of FIGS. 8A-8C, and similar detailed description is omitted.

In some embodiments, the set of conductors 1350 is similar to the set of conductors 850 of FIGS. 8A-8C, and similar detailed description is omitted.

The set of conductors 1340 includes one or more of conductors 1340a or 1340b.

In some embodiments, each of conductors 1340a or 1340b of the set of conductors 1340 is similar to corresponding conductor 840a or 840b of the set of conductors 840 of FIGS. 8A-8C, and similar detailed description is omitted.

The set of conductors 1350 includes one or more of conductors 1350a, 1350b, 1350c or 1350d.

In some embodiments, each of conductors 1350a, 1350b, 1350c or 1350d of the set of conductors 1350 is similar to one or more of conductor 850a or 850b of the set of conductors 850 of FIGS. 8A-8C, and similar detailed description is omitted.

In a non-limiting example, formulas 1-4 are applied to integrated circuit 1300. For example, integrated circuit 1300 includes 4 M1 fingers and 2 M0 fingers, and a number of CPPs that is equal to 29 CPPs. Furthermore, in this non-limiting example, the height H4 is equal to 2 since cell 1302 is a double height cell.

In some embodiments, applying formula 1 yields, the Ratio R1 to be equal to 4/29, which is equal to 13.7%. In some embodiments, when the ratio R1 is 13.7%, then ratio R1 is between 10% and 35%, and thereby satisfies formula 2.

In some embodiments, applying formula 3 yields, the Ratio R2 to be equal to 2/2, which is equal to 1. In some embodiments, when the ratio R2 is 1, then ratio R2 is equal to 1, and thereby satisfies formula 4.

In some embodiments, integrated circuit 1300 is configured to achieve one or more benefits described herein including the details discussed herein.

Other configurations, arrangements on other levels or quantities of elements in integrated circuit 1300 are within the scope of the present disclosure.

FIGS. 14A-14B are functional flow charts of method 1400 of manufacturing an IC device, in accordance with some embodiments. It is understood that additional operations may be performed before, during, and/or after the method 1400 depicted in FIGS. 14A-14B, and that some other processes may only be briefly described herein.

In some embodiments, other order of operations of method 1400-1600 is within the scope of the present disclosure. Method 1400-1600 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 1400, 1500 or 1600 is not performed.

In some embodiments, method 1400 is an embodiment of operation 804 of method 800. In some embodiments, the methods 1400-1600 are usable to manufacture or fabricate at least integrated circuit integrated circuit 100, 200A-200H, 300, 400, 500, 600, 700A, 700B, 800, 900, 1000, 1100, 1200 or 1300.

In operation 1402 of method 1400, a first set of transistors is fabricated in a front-side 303a of a semiconductor wafer or substrate 390 in at least a first cell region.

In some embodiments, the first cell region of method 1400 includes at least one cell of cells 202a, 803, 903, 1003, 1102, 1202 or 1302.

In some embodiments, the first set of transistors of method 1400 includes one or more transistors in at least the set of active regions 802. In some embodiments, the first set of transistors of method 1400 includes one or more transistors described herein.

In some embodiments, the first cell region extends in the first direction X, and has a first cell height in the second direction Y.

In some embodiments, the first set of transistors includes at least one of a set of buffer circuits B1, B2, B3, B4 or B5 of a clock circuit or at least one of a set of inverters I1, I2 or I3 of the clock circuit.

In some embodiments, the first cell height includes at least one of height H1 or H4.

In some embodiments, operation 1402 includes fabricating source and drain regions of the set of transistors in a first well (e.g., wells 303 and 503). In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interact with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 1402 further includes operation 1402a. In some embodiments, operation 1402a includes forming a first gate region of the first set of transistors. In some embodiments, the first gate region of the first set of transistors of method 1400 includes the set of gates 804.

In some embodiments, operation 1402 further includes operation 1402b. In some embodiments, operation 1402b includes forming a second gate region of the second set of transistors. In some embodiments, the second gate regions of the second set of transistors of method 1400 include the set of gates 304.

In some embodiments, the first and second gate region is between the drain region and the source region. In some embodiments, the first and second gate region is over the first well and the substrate. In some embodiments, fabricating the first and second gate regions of operations 1402a and 1402c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the first set of transistors of operation 1402b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the first set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 1402a and 1402b are replaced by forming one or more first gate regions of the first set of transistors and one or more second gate regions of the second set of transistors, removing a portion of the first gate regions of the first set of transistors and the second gate regions of the second set of transistors, and forming an insulating material between the first gate structure of the first set of transistors and the second gate structure of the second set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, operation 1402 further includes fabricating portions of a second set of transistors in a second cell region. In some embodiments, the portions of the second set of transistors in the second cell region includes fabricating a second set of active regions in the second cell region, and fabricating a second set of gates in the second cell region.

In some embodiments, the second set of transistors of method 1400 includes one or more transistors in at least the set of active regions 302. In some embodiments, the second set of transistors of method 1400 includes one or more transistors described herein.

In some embodiments, the second set of active regions of method 1400 includes the set of active regions 302. In some embodiments, the second set of gates of method 1400 includes the set of gates 304.

In operation 1404 of method 1400, a set of FTVs is formed in a second cell region.

In some embodiments, the second cell region of method 1400 includes at least one cell of cells 204a, 204b, 204c, 206a, 206b, 206c, 301, 802, 902, 1002, 1104, 1106, 1204, 1206 or 1304.

In some embodiments, the set of FTVs of method 1400 includes at least one FTV of the set of FTVs 391, 491, 591, 691, 1191, 1192, 1291, 1292 or 1391.

In some embodiments, the second cell region extends in the first direction X and has a second height in the second direction Y. In some embodiments, the second cell height of method 1400 includes at least one of height H2, H3 or H5.

In some embodiments, the second height is different from the first height.

In some embodiments, the second cell region is adjacent to the first cell region along a first boundary. In some embodiments, the first boundary of method 1400 includes at least one of cell boundaries 201a or 201b.

In some embodiments, the first boundary extends in the first direction X.

In some embodiments, operation 1404 comprises at least one of operations 1406, 1408, 1410, 1412, 1414 or 1416.

In operation 1406 of method 1400, a first conductive material is deposited on the front-side 303a of the substrate on a first level thereby forming a first set of contacts.

In some embodiments, the first set of contacts extend in at least the first direction X or the second direction Y.

In some embodiments, the first set of conductors of method 1400 includes one or more portions of at least the set of contacts 306, 406, 506, 806, 1116, 1118, 1216, 1218 or 1316.

In some embodiments, the first level of method 1400 is the MD level.

In operation 1408 of method 1400, a first set of gates is fabricated on the front-side of the substrate on a second level.

In some embodiments, the first set of gates of method 1400 includes at least one of the set of gates 304 or 604.

In some embodiments, the first set of gates extends in the second direction Y.

In some embodiments, the second level of method 1400 is the POLY level.

In operation 1410 of method 1400, a second conductive material is deposited on the front-side 303a of the substrate on a third level thereby forming a first set of vias.

In some embodiments, the first set of vias of method 1400 includes one or more portions of at least the set of conductors 330.

In some embodiments, the third level of method 1400 is the VDR level.

In some embodiments, the first set of vias extends in at least the first direction X or the second direction Y, overlaps at least the first set of contacts or the set of gates, and is electrically coupled to at least the first set of contacts or the first set of gates.

In operation 1412 of method 1400, thinning is performed on the back-side 303b of the wafer or substrate. In some embodiments, operation 1408 includes a thinning process performed on the back-side 303b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 303b of the semiconductor wafer or substrate.

In operation 1414 of method 1400, a first portion of the back-side of the substrate is removed thereby forming a first opening in the substrate.

In some embodiments, operation 1414 includes one or more etching operations. In some embodiments, the one or more etching operations of operation 1414 includes a wet etching process or a dry etching process. In some embodiments, the etch process is performed using RIE, wet etching, or other suitable techniques.

In operation 1416 of method 1400, a third conductive material is deposited in the first opening of the substrate thereby forming a first set of conductors.

In some embodiments, the first set of conductors extends in the first direction X, is on a fourth level and is electrically coupled to the first set of contacts. In some embodiments, the fourth level is different from the first level, the second level and the third level.

In some embodiments, the fourth level of method 1400 is the FTC level.

In some embodiments, the first set of conductors of method 1400 includes one or more conductors of the set of conductors 322.

In operation 1418 of method 1400, a fourth conductive material is deposited on a back-side of the substrate on a first metal level thereby forming a second set of conductors.

In some embodiments, the back-side of the substrate is opposite from the front-side of the substrate. In some embodiments, the second set of conductors extends in the first direction X, and is electrically coupled to the first set of conductors.

In some embodiments, the first metal level of method 1400 is the BM0 level.

In some embodiments, the second set of conductors of method 1400 includes one or more conductors of the set of conductors 320.

In operation 1420 of method 1400, a fifth conductive material is deposited on the front-side of the substrate on a second metal level thereby forming a third set of conductors.

In some embodiments, the third set of conductors extends in the first direction X, and is electrically coupled to the first set of vias.

In some embodiments, the second metal level of method 1400 is the M0 level.

In some embodiments, the third set of conductors of method 1400 includes one or more conductors of the set of conductors 840, 1140, 1240 or 1340.

In operation 1422 of method 1400, a second set of vias are formed over the third set of conductors.

In some embodiments, the second set of vias is electrically coupled to the third set of conductors.

In some embodiments, the second set of vias is on the V0 level.

In some embodiments, the second set of vias of method 1400 includes one or more portions at least the set of vias 842.

In some embodiments, operation 1420 includes forming a first set of self-aligned contacts (SACs) in the insulating layer over the front-side 303a of the wafer.

In operation 1424 of method 1400, a sixth conductive material is deposited on the front-side of the substrate on a third metal level thereby forming a fourth set of conductors.

In some embodiments, the fourth set of conductors extends in the second direction Y, overlaps the third set of conductors, and is electrically coupled to the third set of conductors by the first set of vias.

In some embodiments, the third metal level of method 1400 is the M1 level.

In some embodiments, the fourth set of conductors of method 1400 includes one or more conductors of the set of conductors 850, 1150, 1152, 1250 or 1350.

In some embodiments, one or more of operations 1402, 1404, 1406, 1410, 1414, 1416, 1418, 1420, 1422 or 1424 of methods 1400 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

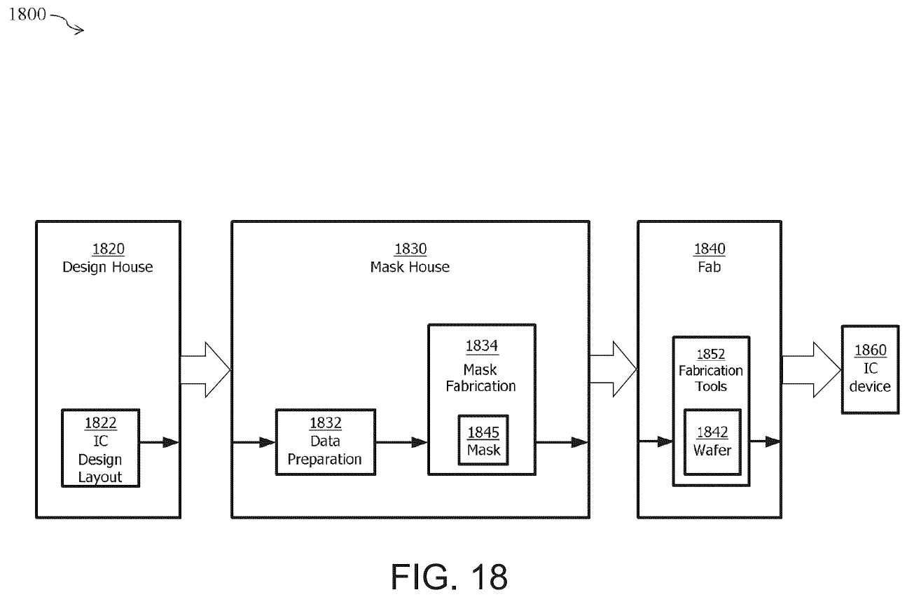

In some embodiments, at least one or more of operations of method 1400 is performed by system 1800 of FIG. 18. In some embodiments, at least one method(s), such as method 1400 discussed above, is performed in whole or in part by at least one manufacturing system, including system 1800.

One or more of the operations of method 1400 is performed by IC fab 1840 (FIG. 18) to fabricate IC device 1860. In some embodiments, one or more of the operations of method 1400 is performed by fabrication tools 1852 to fabricate wafer 1842.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 1402, 1406, 1410, 1416, 1418, 1420, 1422 or 1424, the conductive material is planarized to provide a level surface for subsequent steps.

In some embodiments, one or more of the operations of method 1400, 1500 or 1600 is not performed.

One or more of the operations of methods 1500-1600 is performed by a processing device configured to execute instructions for manufacturing an integrated circuit, such as at least integrated circuit integrated circuit 100, 200A-200H, 300, 400, 500, 600, 700A, 700B, 800, 900, 1000, 1100, 1200 or 1300. In some embodiments, one or more operations of methods 1500-1600 is performed using a same processing device as that used in a different one or more operations of methods 1500-1600. In some embodiments, a different processing device is used to perform one or more operations of methods 1500-1600-900 from that used to perform a different one or more operations of methods 1500-1600. In some embodiments, other order of operations of method 1400, 1500 or 1600 is within the scope of the present disclosure. Method 1400, 1500 or 1600 includes exemplary operations, but the operations are not necessarily performed in the order shown. Operations in method 1400, 1500 or 1600 may be added, replaced, changed order, and/or eliminated as appropriate, in accordance with the spirit and scope of disclosed embodiments.

FIG. 15 is a flowchart of a method 1500 of forming or manufacturing an integrated circuit in accordance with some embodiments. It is understood that additional operations may be performed before, during, and/or after the method 1500 depicted in FIG. 15, and that some other operations may only be briefly described herein. In some embodiments, the method 1500 is usable to form integrated circuits, such as at least integrated circuit 100, 200A-200H, 300, 400, 500, 600, 700A, 700B, 800, 900, 1000, 1100, 1200 or 1300.

In operation 1502 of method 1500, a layout design of an integrated circuit is generated.

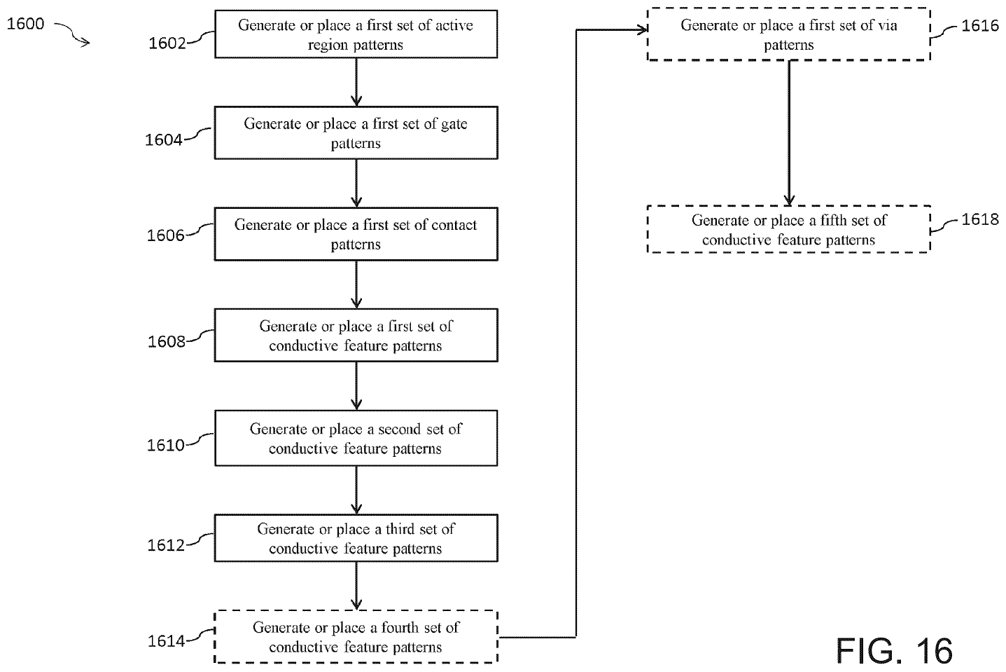

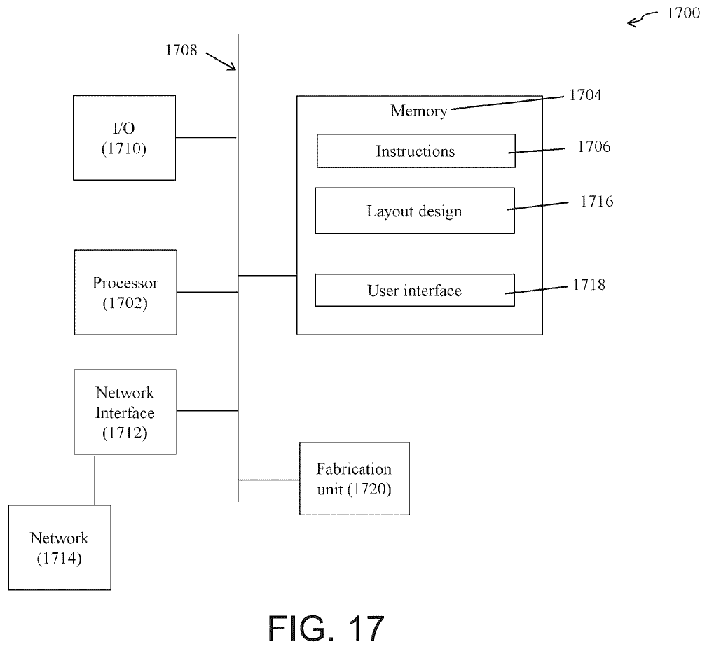

Operation 1502 is performed by a processing device (e.g., processor 1702 (FIG. 17)) configured to execute instructions for generating a layout design. In some embodiments, the layout design of method 1500 includes one or more patterns similar to one or more features of at least integrated circuit 100, 200A-200H, 300, 400, 500, 600, 700A, 700B, 800, 900, 1000, 1100, 1200 or 1300. In some embodiments, the layout design of the present application is in a graphic database system (GDSII) file format. In some embodiments, operation 1502 corresponds to method 1600 of FIG. 16.

In operation 1504 of method 1500, the integrated circuit is manufactured based on the layout design. In some embodiments, operation 1504 of method 1500 comprises manufacturing at least one mask based on the layout design, and manufacturing the integrated circuit based on the at least one mask. In some embodiments, operation 1504 corresponds to method 1400 of FIGS. 14A-14B.

FIG. 16 is a flowchart of a method 1600 of generating a layout design of an integrated circuit, in accordance with some embodiments. It is understood that additional operations may be performed before, during, and/or after the method 1600 depicted in FIG. 16, and that some other processes may only be briefly described herein. In some embodiments, method 1600 is an embodiment of operation 1502 of method 1500. In some embodiments, method 1600 is usable to generate one or more layout patterns or one or more features similar to at least integrated circuit 100, 200A-200H, 300, 400, 500, 600, 700A, 700B, 800, 900, 1000, 1100, 1200 or 1300.

In some embodiments, method 1600 is usable to generate one or more layout patterns having structural relationships including alignment, lengths and widths, as well as configurations and layers similar to one or more features of at least integrated circuit 100, 200A-200H, 300, 400, 500, 600, 700A, 700B, 800, 900, 1000, 1100, 1200 or 1300, and similar detailed description will not be described in FIG. 16, for brevity.

In operation 1602 of method 1600, a first set of active region patterns is generated or placed on the layout design. In some embodiments, the first set of active region patterns of method 1600 includes one or more regions similar to at least one of the set of active regions 302 or 802. In some embodiments, the first set of active region patterns of method 1600 includes one or more patterns or similar patterns in the OD layer.

In operation 1604 of method 1600, a first set of gate patterns is generated or placed on the layout design. In some embodiments, the first set of gate patterns of method 1600 includes one or more regions similar to at least one of the set of gates 304 or 804. In some embodiments, the first set of gate patterns of method 1600 includes one or more patterns or similar patterns in the POLY layer.

In operation 1606 of method 1600, a first set of contact patterns is generated or placed on the layout design. In some embodiments, the first set of contact patterns of method 1600 includes one or more patterns similar to the set of contacts 306, 406, 506, 806, 1116, 1118, 1216, 1218 or 1316. In some embodiments, the first set of contact patterns of method 1600 includes one or more patterns or similar patterns in the MD layer.

In operation 1608 of method 1600, a first set of conductive feature patterns is generated or placed on the layout design. In some embodiments, the first set of conductive feature patterns of method 1600 includes one or more patterns similar to the set of conductors 320. In some embodiments, the first set of conductive feature patterns of method 1600 includes one or more patterns or similar patterns in the BM0 layer.

In operation 1610 of method 1600, a second set of conductive feature patterns is generated or placed on the layout design. In some embodiments, the second set of conductive feature patterns of method 1600 includes one or more patterns similar to the set of conductors 322. In some embodiments, the second set of conductive feature patterns of method 1600 includes one or more patterns or similar patterns in the FTC layer.

In operation 1612 of method 1600, a third set of conductive feature patterns is generated or placed on the layout design. In some embodiments, the third set of conductive feature patterns of method 1600 includes one or more patterns similar to the set of conductors 330. In some embodiments, the third set of conductive feature patterns of method 1600 includes one or more patterns or similar patterns in the VDR layer.

In some embodiments, at least one or more of operations 1606, 1610 or 1612 correspond to generating or placing a set of FTV patterns on the layout design. In some embodiments, the set of FTV patterns of method 1600 includes one or more patterns or similar conductors in the MD layer, the FTC layer and the VDR layer.

In operation 1614 of method 1600, a fourth set of conductive feature patterns is generated or placed on the layout design. In some embodiments, the fourth set of conductive feature patterns of method 1600 includes one or more conductive feature patterns similar to at least the set of conductors 840, 1140, 1240 or 1340. In some embodiments, the fourth set of conductive feature patterns of method 1600 includes one or more patterns or similar conductors in the M0 layer.

In operation 1616 of method 1600, a first set of via patterns is generated or placed on the layout design. In some embodiments, the first set of via patterns of method 1600 includes one or more via patterns similar to at least the set of vias 842. In some embodiments, the first set of via patterns of method 1600 includes one or more patterns or similar vias in the V0 layer.

In operation 1618 of method 1600, a fifth set of conductive feature patterns is generated or placed on the layout design. In some embodiments, the fifth set of conductive feature patterns of method 1600 includes one or more conductive feature patterns similar to at least the set of conductors 850, 1150, 1152, 1250 or 1350. In some embodiments, the fifth set of conductive feature patterns of method 1600 includes one or more patterns or similar conductors in the M1 layer.

FIG. 17 is a schematic view of a system 1700 for designing an IC layout design and manufacturing an IC circuit in accordance with some embodiments.

In some embodiments, system 1700 generates or places one or more IC layout designs described herein. System 1700 includes a hardware processor 1702 and a non-transitory, computer readable storage medium 1704 (e.g., memory 1704) encoded with, i.e., storing, the computer program code 1706, i.e., a set of executable instructions 1706. Computer readable storage medium 1704 is configured for interfacing with manufacturing machines for producing the integrated circuit. The processor 1702 is electrically coupled to the computer readable storage medium 1704 by a bus 1708. The processor 1702 is also electrically coupled to an I/O interface 1710 by bus 1708. A network interface 1712 is also electrically connected to the processor 1702 via bus 1708. Network interface 1712 is connected to a network 1714, so that processor 1702 and computer readable storage medium 1704 are capable of connecting to external elements by network 1714. The processor 1702 is configured to execute the computer program code 1706 (e.g., non-transitory instructions) encoded in the computer readable storage medium 1704 in order to cause system 1700 to be usable for performing a portion or all of the operations as described in method 1500-1600.

In some embodiments, the processor 1702 is a central processing unit (CPU), a multi-processor, a distributed processing system, an application specific integrated circuit (ASIC), and/or a suitable processing unit.

In some embodiments, the computer readable storage medium 1704 is an electronic, magnetic, optical, electromagnetic, infrared, and/or a semiconductor system (or apparatus or device). For example, the computer readable storage medium 1704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1704 includes a compact disk-read only memory (CD-ROM), a compact disk-read/write (CD-R/W), and/or a digital video disc (DVD).

In some embodiments, the storage medium 1704 stores the computer program code 1706 (also referred to as “instructions 1706”) configured to cause system 1700 to perform method 1500-1600. In some embodiments, the storage medium 1704 also stores information needed for performing method 1500-1600 as well as information generated during performing method 1500-1600, such as layout design 1716, user interface 1718 and fabrication unit 1720, and/or a set of executable instructions to perform the operation of method 1500-1600. In some embodiments, layout design 1716 comprises one or more features similar to at least integrated circuit 100, 200A-200H, 300, 400, 500, 600, 700A, 700B, 800, 900, 1000, 1100, 1200 or 1300.

In some embodiments, the storage medium 1704 stores instructions (e.g., computer program code 1706) for interfacing with manufacturing machines. The instructions (e.g., computer program code 1706) enable processor 1702 to generate manufacturing instructions readable by the manufacturing machines to effectively implement method 1500-1600 during a manufacturing process.

System 1700 includes I/O interface 1710. I/O interface 1710 is coupled to external circuitry. In some embodiments, I/O interface 1710 includes a keyboard, keypad, mouse, trackball, trackpad, and/or cursor direction keys for communicating information and commands to processor 1702.

System 1700 also includes network interface 1712 coupled to the processor 1702. Network interface 1712 allows system 1700 to communicate with network 1714, to which one or more other computer systems are connected. Network interface 1712 includes wireless network interfaces such as BLUETOOTH, WIFI, WIMAX, GPRS, or WCDMA; or wired network interface such as ETHERNET, USB, or IEEE-2094. In some embodiments, method 1500-1600 is implemented in two or more systems 1700, and information such as layout design, and user interface are exchanged between different systems 1700 by network 1714.

System 1700 is configured to receive information related to a layout design through I/O interface 1710 or network interface 1712. The information is transferred to processor 1702 by bus 1708 to determine a layout design for producing at least integrated circuit 100, 200A-200H, 300, 400, 500, 600, 700A, 700B, 800, 900, 1000, 1100, 1200 or 1300. The layout design is then stored in computer readable medium 1704 as layout design 1716. System 1700 is configured to receive information related to a user interface through I/O interface 1710 or network interface 1712. The information is stored in computer readable medium 1704 as user interface 1718. System 1700 is configured to receive information related to a fabrication unit 1720 through I/O interface 1710 or network interface 1712. The information is stored in computer readable medium 1704 as fabrication unit 1720. In some embodiments, the fabrication unit 1720 includes fabrication information utilized by system 1700. In some embodiments, the fabrication unit 1720 corresponds to mask fabrication 1834 of FIG. 18.

In some embodiments, method 1500-1600 is implemented as a standalone software application for execution by a processor. In some embodiments, method 1500-1600 is implemented as a software application that is a part of an additional software application. In some embodiments, method 1500-1600 is implemented as a plug-in to a software application. In some embodiments, method 1500-1600 is implemented as a software application that is a portion of an EDA tool. In some embodiments, method 1500-1600 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1500-1600 is implemented by a manufacturing device to manufacture an integrated circuit using a set of masks manufactured based on one or more layout designs generated by system 1700. In some embodiments, system 1700 is a manufacturing device configured to manufacture an integrated circuit using a set of masks manufactured based on one or more layout designs of the present disclosure. In some embodiments, system 1700 of FIG. 17 generates layout designs of an integrated circuit that are smaller than other approaches. In some embodiments, system 1700 of FIG. 17 generates layout designs of integrated circuit structure that occupy less area and provide better routing resources than other approaches.

FIG. 18 is a block diagram of an integrated circuit (IC) manufacturing system 1800, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1800.

In FIG. 18, IC manufacturing system 1800 (hereinafter “system 1800”) includes entities, such as a design house 1820, a mask house 1830, and an IC manufacturer/fabricator (“fab”) 1840, that interact with one another in the design, development, and manufacturing cycles and/or services related to manufacturing an IC device 1860. The entities in system 1800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1820, mask house 1830, and IC fab 1840 is owned by a single larger company. In some embodiments, one or more of design house 1820, mask house 1830, and IC fab 1840 coexist in a common facility and use common resources.

Design house (or design team) 1820 generates an IC design layout 1822. IC design layout 1822 includes various geometrical patterns designed for an IC device 1860. The geometrical patterns correspond to patterns of metal, oxide, or semiconductor layers that make up the various components of IC device 1860 to be fabricated. The various layers combine to form various IC features. For example, a portion of IC design layout 1822 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1820 implements a proper design procedure to form IC design layout 1822. The design procedure includes one or more of logic design, physical design or place and route. IC design layout 1822 is presented in one or more data files having information of the geometrical patterns. For example, IC design layout 1822 can be expressed in a GDSII file format or DFII file format.

Mask house 1830 includes data preparation 1832 and mask fabrication 1834. Mask house 1830 uses IC design layout 1822 to manufacture one or more masks 1845 to be used for fabricating the various layers of IC device 1860 according to IC design layout 1822. Mask house 1830 performs mask data preparation 1832, where IC design layout 1822 is translated into a representative data file (RDF).

Mask data preparation 1832 provides the RDF to mask fabrication 1834. Mask fabrication 1834 includes a mask writer. A mask writer converts the RDF to an image on a substrate, such as a mask (reticle) 1845 or a semiconductor wafer 1842. The IC design layout 1822 is manipulated by mask data preparation 1832 to comply with particular characteristics of the mask writer and/or requirements of IC fab 1840. In FIG. 18, mask data preparation 1832 and mask fabrication 1834 are illustrated as separate elements. In some embodiments, mask data preparation 1832 and mask fabrication 1834 can be collectively referred to as mask data preparation.

In some embodiments, mask data preparation 1832 includes optical proximity correction (OPC) which uses lithography enhancement techniques to compensate for image errors, such as those that can arise from diffraction, interference, other process effects and the like. OPC adjusts IC design layout 1822. In some embodiments, mask data preparation 1832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1834, which may undo part of the modifications performed by OPC in order to meet mask creation rules.

In some embodiments, mask data preparation 1832 includes lithography process checking (LPC) that simulates processing that will be implemented by IC fab 1840 to fabricate IC device 1860. LPC simulates this processing based on IC design layout 1822 to create a simulated manufactured device, such as IC device 1860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1822.

It should be understood that the above description of mask data preparation 1832 has been simplified for the purposes of clarity. In some embodiments, data preparation 1832 includes additional features such as a logic operation (LOP) to modify the IC design layout according to manufacturing rules. Additionally, the processes applied to IC design layout 1822 during data preparation 1832 may be executed in a variety of different orders.

After mask data preparation 1832 and during mask fabrication 1834, a mask 1845 or a group of masks 1845 are fabricated based on the modified IC design layout 1822. In some embodiments, mask fabrication 1834 includes performing one or more lithographic exposures based on IC design layout 1822. In some embodiments, an electron-beam (e-beam) or a mechanism of multiple e-beams is used to form a pattern on a mask (photomask or reticle) 1845 based on the modified IC design layout 1822. The mask 1845 can be formed in various technologies. In some embodiments, the mask 1845 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1845 includes a transparent substrate (e.g., fused quartz) and an opaque material (e.g., chromium) coated in the opaque regions of the binary mask. In another example, the mask 1845 is formed using a phase shift technology. In the phase shift mask (PSM) version of mask 1845, various features in the pattern formed on the mask are configured to have proper phase difference to enhance the resolution and imaging quality. In various examples, the phase shift mask can be attenuated PSM or alternating PSM. The mask(s) generated by mask fabrication 1834 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1840 is an IC fabrication entity that includes one or more manufacturing facilities for the fabrication of a variety of different IC products. In some embodiments, IC Fab 1840 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1840 includes wafer fabrication tools 1852 (hereinafter “fabrication tools 1852”) configured to execute various manufacturing operations on semiconductor wafer 1842 such that IC device 1860 is fabricated in accordance with the mask(s), e.g., mask 1845. In various embodiments, fabrication tools 1852 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1840 uses mask(s) 1845 fabricated by mask house 1830 to fabricate IC device 1860. Thus, IC fab 1840 at least indirectly uses IC design layout 1822 to fabricate IC device 1860. In some embodiments, a semiconductor wafer 1842 is fabricated by IC fab 1840 using mask(s) 1845 to form IC device 1860. In some embodiments, the IC fabrication includes performing one or more lithographic exposures based at least indirectly on IC design layout 1822. Semiconductor wafer 1842 includes a silicon substrate or other proper substrate having material layers formed thereon. Semiconductor wafer 1842 further includes one or more of various doped regions, dielectric features, multilevel interconnects, and the like (formed at subsequent manufacturing steps).

System 1800 is shown as having design house 1820, mask house 1830 or IC fab 1840 as separate components or entities. However, it is understood that one or more of design house 1820, mask house 1830 or IC fab 1840 are part of the same component or entity.

One aspect of this description relates to an integrated circuit. In some embodiments, the integrated circuit includes a first cell region extending in a first direction and having a first height in a second direction different from the first direction. In some embodiments, the first cell region includes a first set of transistors of a clock circuit. In some embodiments, the integrated circuit further includes a second cell region extending in the first direction and having a second height in the second direction, the second height being different from the first height, the second cell region being adjacent to the first cell region along a first boundary, the first boundary extending in the first direction. In some embodiments, the second cell region includes a feed-through via extending from a front-side to a back-side of a substrate, the feed-through via configured to electrically couple elements on the front-side and the back-side together. In some embodiments, the feed-through via includes a first conductor on the back-side of the substrate, and extending in the first direction. In some embodiments, the feed-through via further includes a second conductor extending in the first direction, being on a first level and being above the first conductor. In some embodiments, the feed-through via further includes a first contact extending in at least the first direction or the second direction, being on a second level different from the first level, and being above the first conductor. In some embodiments, the feed-through via further includes a first via extending in the first direction, being on a third level different from the first level and the second level, and being above the first conductor.

Another aspect of this description relates to an integrated circuit. In some embodiments, the integrated circuit includes a first cell region extending in a first direction and having a first height in a second direction different from the first direction, the first cell region including a clock circuit. In some embodiments, the clock circuit includes a set of buffer circuits including a first set of transistors, or a set of inverters including the first set of transistors. In some embodiments, the integrated circuit further includes a second cell region extending in the first direction and having a second height in the second direction, the second height being different from the first height, the second cell region being adjacent to the first cell region along a first boundary, the first boundary extending in the first direction. In some embodiments, the second cell region includes a first set of gates extending in the first direction, and a second set of gates extending in the first direction, and being separated from the first set of gates in the second direction. In some embodiments, the second cell region further includes a feed-through via between the first set of gates and the second set of gates, the feed-through via extending from a front-side to a back-side of a substrate, the feed-through via configured to electrically couple elements on the front-side and the back-side together. In some embodiments, the feed-through via includes a first conductor on the back-side of the substrate, and extending in the first direction. In some embodiments, the feed-through via further includes a second conductor extending in the first direction, being on a first level and being above the first conductor. In some embodiments, the feed-through via further includes a first contact extending in at least the first direction or the second direction, being on a second level different from the first level, and being above the first conductor. In some embodiments, the feed-through via further includes a first via extending in the first direction, being on a third level different from the first level and the second level, and being above the first conductor.

Still another aspect of this description relates to a method of fabricating an integrated circuit. In some embodiments, the method includes fabricating a first set of transistors in a front-side of a substrate in a first cell region, the first cell region extending in a first direction and having a first height in a second direction different from the first direction, the first set of transistors including a set of buffer circuits of a clock circuit, or a set of inverters of the clock circuit. In some embodiments, the method further includes fabricating a feed-through via in a second cell region, the second cell region extending in the first direction and having a second height in the second direction, the second height being different from the first height, the second cell region being adjacent to the first cell region along a first boundary, the first boundary extending in the first direction. In some embodiments, fabricating the feed-through via in the second cell region includes depositing a first conductive material on the front-side of the substrate on a first level thereby forming a first set of contacts, the first set of contacts extending in at least the first direction or the second direction. In some embodiments, fabricating the feed-through via in the second cell region further includes fabricating a first set of gates on the front-side of the substrate on a second level, the first set of gates extending in the second direction. In some embodiments, fabricating the feed-through via in the second cell region further includes depositing a second conductive material on the front-side of the substrate on a third level thereby forming a first set of vias, the first set of vias extending in at least the first direction or the second direction, overlapping at least the first set of contacts or the set of gates, and being electrically coupled to at least the first set of contacts or the first set of gates. In some embodiments, fabricating the feed-through via in the second cell region further includes depositing a third conductive material in a first opening of the substrate thereby forming a first set of conductors, the first set of conductors extending in the first direction, being on a fourth level and being electrically coupled to the first set of contacts, the fourth level being different from the first level, the second level and the third level. In some embodiments, the method further includes depositing a fourth conductive material on a back-side of the substrate on a first metal level thereby forming a second set of conductors, the back-side of the substrate being opposite from the front-side of the substrate, the second set of conductors extending in the first direction, and being electrically coupled to the first set of conductors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first cell region extending in a first direction and having a first height in a second direction different from the first direction, the first cell region comprising:
a first set of transistors of a clock circuit;
a second cell region extending in the first direction and having a second height in the second direction, the second height being different from the first height, the second cell region being adjacent to the first cell region along a first boundary, the first boundary extending in the first direction, the second cell region comprising:
a feed-through via extending from a front-side to a back-side of a substrate, the feed-through via configured to electrically couple elements on the front-side and the back-side together, the feed-through via comprising:
a first conductor on the back-side of the substrate, and extending in the first direction;
a second conductor extending in the first direction, being on a first level and being above the first conductor;
a first contact extending in at least the first direction or the second direction, being on a second level different from the first level, and being above the first conductor; and
a first via extending in the first direction, being on a third level different from the first level and the second level, and being above the first conductor.

2. The integrated circuit of claim 1, wherein the clock circuit comprises:
a set of buffer circuits including the first set of transistors; or
a set of inverters including the first set of transistors.

3. The integrated circuit of claim 1, wherein the second cell region further comprises:
a first active region extending in the first direction, and being on a fourth level, and the first active region including a first dopant type; and
a second active region extending in the first direction, being on the fourth level, and being separated from the first active region in the first direction, and the second active region including a second dopant type different from the first dopant type,
wherein the feed-through via is between the first active region and the second active region.

4. The integrated circuit of claim 3, wherein the first cell region further comprises:
a third active region extending in the first direction, and being on the fourth level, and the third active region including the second dopant type; and
a fourth active region extending in the first direction, being on the fourth level, and being separated from the third active region in the first direction, and the fourth active region including the first dopant type.

5. The integrated circuit of claim 4, wherein the second cell region further comprises:
a first gate extending in the first direction, and being on a fifth level different from the first level, the third level and the fourth level, and the first gate overlapping at least the first active region;
a second gate extending in the first direction, being on the fifth level, and overlapping at least the first active region; and
a third gate extending in the first direction, being on the fifth level, and overlapping at least the first active region,
wherein the first gate, the second gate and the third gate are separated from each other in the first direction.

6. The integrated circuit of claim 5, wherein the feed-through via further comprises:
a second contact extending in the second direction, being on the second level, and being above the first conductor,
wherein the first contact is between the first gate and the second gate; and
the second contact is between the second gate and the third gate.

7. The integrated circuit of claim 6, wherein the first gate, the second gate and the third gate further overlap the second active region.

8. The integrated circuit of claim 7, wherein the first gate, the second gate and the third gate overlap the first boundary of the first cell region, the third active region and the fourth active region.

9. The integrated circuit of claim 8, wherein
the first gate, the second gate and the third gate are corresponding gates of one or more transistors in the first set of transistors of the clock circuit, and
the feed-through via is configured to supply a clock input signal to the corresponding gates of one or more transistors in the first set of transistors of the clock circuit.

10. An integrated circuit, comprising:
a first cell region extending in a first direction and having a first height in a second direction different from the first direction, the first cell region including a clock circuit, the clock circuit comprising:
a set of buffer circuits including a first set of transistors; or
a set of inverters including the first set of transistors; and
a second cell region extending in the first direction and having a second height in the second direction, the second height being different from the first height, the second cell region being adjacent to the first cell region along a first boundary, the first boundary extending in the first direction, the second cell region including:
a first set of gates extending in the first direction; and
a second set of gates extending in the first direction, and being separated from the first set of gates in the second direction; and
a feed-through via between the first set of gates and the second set of gates, the feed-through via extending from a front-side to a back-side of a substrate, the feed-through via configured to electrically couple elements on the front-side and the back-side together, the feed-through via comprising:
a first conductor on the back-side of the substrate, and extending in the first direction;
a second conductor extending in the first direction, being on a first level and being above the first conductor;
a first contact extending in at least the first direction or the second direction, being on a second level different from the first level, and being above the first conductor; and
a first via extending in the first direction, being on a third level different from the first level and the second level, and being above the first conductor.

11. The integrated circuit of claim 10, wherein the second cell region further comprises:
a first active region extending in the first direction, and being on a fourth level, and the first active region including a first dopant type; and
a second active region extending in the first direction, being on the fourth level, and being separated from the first active region in the first direction, and the second active region including a second dopant type different from the first dopant type,
wherein the feed-through via is between the first active region and the second active region.

12. The integrated circuit of claim 11, wherein the first cell region further comprises:
a third active region extending in the first direction, and being on the fourth level, and the third active region including the second dopant type; and
a fourth active region extending in the first direction, being on the fourth level, and being separated from the third active region in the first direction, and the fourth active region including the first dopant type.

13. The integrated circuit of claim 12, wherein the first contact is between a first gate of the first set of gates and a second gate of the second set of gates.

14. The integrated circuit of claim 12, wherein the feed-through via further comprises:
a second contact extending in the second direction, being on the second level, and being above the first conductor,
wherein the first contact and the second contact are between the first active region and the second active region.

15. The integrated circuit of claim 14, wherein
the first set of gates comprises:
a first gate overlapping the first active region;
a second gate overlapping the first active region; and
a third gate overlapping the first active region, the second gate being between the first gate and the second gate;
the second set of gates comprises:
a fourth gate overlapping the second active region;
a fifth gate overlapping the second active region; and
a sixth gate overlapping the second active region, the fifth gate being between the fourth gate and the sixth gate.

16. The integrated circuit of claim 15, wherein the first contact and the second contact overlap the first active region or the second active region.

17. The integrated circuit of claim 16, wherein the first contact and the second contact overlap the first boundary of the first cell region, the third active region and the fourth active region.

18. The integrated circuit of claim 17, wherein
the first contact and the second contact are corresponding drains/sources of one or more transistors in the first set of transistors of the clock circuit, and
the first contact and the second contact are configured to supply an clock output signal to the feed-through via.

19. The integrated circuit of claim 15, further comprising:
a first set of conductors extending in the first direction, being on a fifth level, and overlapping the feed-through via, the third active region and the fourth active region;
a second set of conductors extending in the second direction, being on a sixth level, and overlapping the first set of conductors, the feed-through via, the third active region and the fourth active region; and
a first set of vias between the first set of conductors and the second set of conductors,
wherein the second set of conductors is configured to supply an clock output signal to the feed-through via or to receive a clock input signal from the feed-through via.

20. A method of fabricating an integrated circuit, the method comprising:
fabricating a first set of transistors in a front-side of a substrate in a first cell region, the first cell region extending in a first direction and having a first height in a second direction different from the first direction, the first set of transistors including a set of buffer circuits of a clock circuit, or a set of inverters of the clock circuit;
fabricating a feed-through via in a second cell region, the second cell region extending in the first direction and having a second height in the second direction, the second height being different from the first height, the second cell region being adjacent to the first cell region along a first boundary, the first boundary extending in the first direction, wherein fabricating the feed-through via in the second cell region comprises:
depositing a first conductive material on the front-side of the substrate on a first level thereby forming a first set of contacts, the first set of contacts extending in at least the first direction or the second direction;
fabricating a first set of gates on the front-side of the substrate on a second level, the first set of gates extending in the second direction;
depositing a second conductive material on the front-side of the substrate on a third level thereby forming a first set of vias, the first set of vias extending in at least the first direction or the second direction, overlapping at least the first set of contacts or the set of gates, and being electrically coupled to at least the first set of contacts or the first set of gates; and
depositing a third conductive material in a first opening of the substrate thereby forming a first set of conductors, the first set of conductors extending in the first direction, being on a fourth level and being electrically coupled to the first set of contacts, the fourth level being different from the first level, the second level and the third level; and
depositing a fourth conductive material on a back-side of the substrate on a first metal level thereby forming a second set of conductors, the back-side of the substrate being opposite from the front-side of the substrate, the second set of conductors extending in the first direction, and being electrically coupled to the first set of conductors.
